(19) United States
(12) Patent Application Publication
(10) Pub. No.: US 2026/0227531 A1
(43) Pub. Date: Aug. 6, 2026

(54) Detector, Measurement Device, and Charged Particle Beam Apparatus

(71) Applicant: Hitachi High-Tech Corporation, Minato-ku, Tokyo (JP)

(72) Inventors: Yoshifumi SEKIGUCHI, Tokyo (JP); Yusuke NAKAMURA, Tokyo (JP); Shin IMAMURA, Tokyo (JP); Takeyoshi OHASHI, Tokyo (JP); Yusuke ABE, Tokyo (JP)

(21) Appl. No.: 19/149,606

(22) PCT Filed: Mar. 15, 2023
(86) PCT No.: PCT/JP2023/010097

§ 371 Date: Jul. 21, 2025

(51) Int. Cl. G01T 1/20; G01T 1/24

(52) U.S. Cl. CPC G01T 1/2002; G01T 1/20187; G01T 1/248

(57) ABSTRACT

The detector includes a light emitting element configured to emit light due to collision of a quantum emitted from a sample by irradiating the sample with a beam, and a plurality of light receiving elements each configured to receive light generated by the light emitting element on a light receiving surface. The light receiving surface is disposed at a position farther from the beam than the light emitting element in a first direction intersecting an irradiation direction of the beam, the light receiving surface is disposed in a direction intersecting the irradiation direction of the beam, and the detector forms a first optical path that guides light in the first direction and a second optical path that guides light arriving via the first optical path toward the light receiving surface.

### TECHNICAL FIELD

The present invention relates to a detector, a measurement device, and a charged particle beam apparatus.

### BACKGROUND ART

A detector is used to convert a particle beam such as electrons and ions and radiation such as X-rays and gamma rays into an electrical signal. When a detection target is charged particles, it is called a charged particle detector, and when a detection target is radiation, it is called a radiation detector.

For example, in a charged particle device using a charged particle beam such as electrons, such as a scanning electron microscope (SEM), a main signal to be detected is charged particles such as electrons, and the charged particle device includes a charged particle detector that detects the charged particles. The SEM irradiates a sample to be observed with an electron beam generated by an electron source and causes a detector to detect electrons emitted from the sample. The charged particle detector outputs an electrical signal corresponding to an amount of the detected electrons. An SEM image is formed by two-dimensionally displaying a relationship between the electrical signal and an electron beam irradiation position on the sample.

Many of such charged particle detectors include a light emitting element that converts detected electrons into photons, a light receiving element that detects the photons from the light emitting element and converts the photons into electrical signals, and a light guide that delivers light emitted by the light emitting element to the light receiving element. A photomultiplier tube (PMT), a silicon photomultiplier (SiPM), or the like is used as the light receiving element. With the same configuration, a radiation detector can be implemented by changing a type of the light emitting element. That is, the radiation detector includes a light emitting element that converts detected radiation into light having a wavelength that can be detected by a light receiving element, and delivers the light from the light emitting element to the light receiving element via a light guide.

Recently, detectors are required to have various kinds of performance. For example, in order to improve S/N of an SEM image, it is important to provide a detector whose output signal is not saturated when an emission amount of an electron beam increases. In order to obtain an observation image with accurate contrast without saturation, PTL 1 proposes a detector including a scintillator, a light guide, and a photodetector, in which an area of a detection surface of the photodetector is larger than an area of a detection surface of the scintillator.

PTL 2 proposes a charged particle beam apparatus that aims to cover a wide detection angle range of charged particles emitted from a sample.

PTL 3 proposes a charged particle beam apparatus using a light guide capable of improving light utilization efficiency which is a ratio of light emitted by a light emitting element to light reaching a light receiving element.

### CITATION LIST

### Patent Literature

PTL 1: WO2021/176513
PTL 2: JP2022-37226A
PTL 3: WO2020/059114

### SUMMARY OF INVENTION

### Technical Problem

When a sample is irradiated with an electron beam, signal electrons are radially emitted from an irradiation region (referred to as an observation point) having a width of several tens of μm. In order to efficiently capture the signal electrons, a shape of a light emitting element is preferably an isotropic shape such as an annular shape. When the shape of the light emitting element is an annular shape, an emission surface from which light is emitted from the light emitting element also has an annular shape.

On the other hand, a light receiving surface of a light receiving element that receives light generally has a quadrangular shape. Therefore, in order to efficiently capture the signal electrons and convert the signal electrons into signals using the light receiving element, a light guide for irradiating the quadrangular light receiving surface with the light emitted from the emission surface of the annular light emitting element is required. When an area of the light receiving surface is sufficiently large as compared with an area of the emission surface of the light emitting element and the light receiving surface and the light emitting element are sufficiently separated from each other, the light guide for connecting the light receiving surface and the light emitting element can be formed, but a structure becomes large.

However, when a detector is large in size, an arrangement of the detector in an SEM is limited. In particular, a thin and compact detector is required in order to dispose the detector in the vicinity of a sample to acquire more signals, and the detector is not compatible with the light guide in which the above-described structure is large, and as a result, it is not possible to achieve both high efficiency detection of signal electrons radially emitted and a thin and compact detector.

Therefore, it is challenge to provide a detector configuration in which the detector is thin, is disposed in a manner of surrounding an observation point in a light emitting element, efficiently captures signal electrons, and delivers emitted light to a light receiving element with a low loss.

PTL 1 and PTL 2 do not describe a loss problem of light propagation due to a shape difference between a light emission surface and a light receiving surface. Since the problem is not considered, there is no description about a method for optically coupling an annular light emitting element and a rectangular light receiving element.

PTL 3 does not describe a detector and a light guide that efficiently couples an emission surface of an annular light emitting element and a quadrangular light receiving surface. Although a charged particle detector was described, the above-described problem occurs when a signal is not electrons but radiation.

Another problem is that an output signal of the detector saturates when a current of an electron beam emitted to the sample increases.

When an amount of an electron beam increases, the number of signal electrons emitted from the sample and detected by the detector increases, and an S/N ratio of an SEM image increases, so that there is a demand for increasing the amount of the electron beam (increasing the current). In this case, energy of the signal electrons is converted into photons by a light emitting element, and the number of photons incident on a light receiving element also increases.

However, when a density of incident photons is large relative to an area of a detection surface, the light receiving element saturates and cannot output an electrical signal that is in accurate proportion to the number of incident photons. For example, in an SiPM (for example, manufactured by Hamamatsu Photonics K.K., model: S13360-3050VE), fine quadrangular detection pixels each having a side of about 50 μm are arranged on a quadrangular detection surface having a side of 3 mm, and when photons are incident on each detection pixel, a current pulse signal is generated for each pixel, and the current pulse signal for each pixel represents detection of one photon. However, when a density of incident photons is large and a plurality of photons are incident on the same detection pixel at the same time, a proportional relationship between the number of incident photons and an output current breaks down, and an accurate SEM image cannot be obtained.

This is a problem that a light receiving element saturates when a current of an electron beam increases. PTL 2 and PTL 3 do not describe the problem.

The problem will be described in more details. Signal electrons fly from an observation point to a detector, but an incident position of the signal electrons on a light emitting element is concentrated on a surface of the light emitting element near the observation point. In particular, since a size of the light emitting element cannot be increased in a detector disposed in the vicinity of a sample, a region on which the signal electrons are incident is minute, and an incident density increases. Therefore, when the current increases, saturation of the light receiving element due to a large number of photons generated from a minute region of the light emitting element, that is, a high density of photons becomes a critical problem.

The problem related to signal saturation due to high density light emission from a minute region and a countermeasure for the signal saturation are not described in PTL 1 to 3. The problem is not limited to a charged particle detector, and the same applies to a radiation detector in which a position where radiation is generated and a position where radiation is detected are close to each other.

In order to dispose a detector near an observation point and surround the observation point to efficiently detect signal electrons, it is important to provide a detector structure for optically coupling a thin annular light emission surface and a quadrangular light receiving surface in an efficient manner and a structure for preventing signal saturation even when the structure is used alone, and observation and measurement accuracy of a measurement device such as an SEM is significantly improved by further combining both of the structures.

In view of the above-described circumstances, an object of the invention is to provide a detector, a measurement device, and a charged particle beam apparatus capable of efficiently detecting signal electrons emitted from an observation point and outputting an electrical signal without saturation even when an amount of the signal electrons, radiation, or the like incident on the detector increases.

### Solution to Problem

An example of a detector according to the invention includes:
a light emitting element configured to emit light due to collision of a quantum emitted from a sample by irradiating the sample with a beam; and
a plurality of light receiving elements each configured to receive light generated by the light emitting element on a light receiving surface, in which
the light receiving surface is disposed at a position farther from the beam than the light emitting element in a first direction intersecting an irradiation direction of the beam,
the light receiving surface is disposed in a direction intersecting the irradiation direction of the beam, and
the detector forms
   a first optical path that guides light in the first direction and
   a second optical path that guides light arriving via the first optical path toward the light receiving surface.

An example of a detector according to the invention includes:
a light emitting element configured to emit light due to collision of a quantum emitted from a sample by irradiating the sample with a beam; and
a plurality of light receiving elements each configured to receive light generated by the light emitting element on a light receiving surface, in which
the light receiving surface is disposed at a position farther from the beam than the light emitting element in a first direction intersecting an irradiation direction of the beam,
the detector has a transparent region for propagating light from a surface of the light emitting element where the quantum is incident to the light receiving surface, and
a normal line of the light receiving surface forms an angle of 45 degrees or less with the first direction.

An example of a measurement device according to the invention includes the detector described above.

An example of a charged particle beam apparatus according to the invention includes the detector described above.

### Advantageous Effects of Invention

According to the present disclosure, it is possible to provide a detector, a measurement device, and a charged particle beam apparatus capable of improving detection efficiency and outputting an electrical signal without saturation even when an amount of signal electrons or radiation incident on the detector increases.

### BRIEF DESCRIPTION OF DRAWINGS

FIG. 1 is a schematic diagram showing an SEM.

FIG. 2A is a perspective view showing a configuration example of a detector 5 according to Embodiment 1.

FIG. 2B is a bottom view and a cross-sectional view showing a configuration example of the detector 5 according to Embodiment 1.

FIG. 3A is a perspective view showing a light emitting element 10 according to Embodiment 1.

FIG. 3B is an enlarged view showing the vicinity of a position where the signal electrons 102 are incident.

FIG. 3C shows a result of light ray tracing simulation.

FIG. 3D shows a relationship between an incident angle to a light emitting element and an amount of signal electrons absorbed in the light emitting element without escaping.

FIG. 4A is a perspective view showing a light guide 11 according to Embodiment 1.

FIG. 4B is a perspective view showing the light guide 11 according to Embodiment 1 as viewed in a direction different from that in FIG. 4A.

FIG. 5 is a detailed view showing a light receiving element 12 according to Embodiment 1.

FIG. 6A is a perspective view showing a configuration example of the detector 5 according to Embodiment 2.

FIG. 6B is a bottom view and a cross-sectional view showing a configuration example of the detector 5 according to Embodiment 2.

FIG. 7A is a perspective view showing a configuration example of the detector 5 according to Embodiment 3.

FIG. 7B is a bottom view and a cross-sectional view showing a configuration example of the detector 5 according to Embodiment 3.

FIG. 8A is a perspective view showing a configuration example of the detector 5 according to Embodiment 4.

FIG. 8B is a bottom view and a cross-sectional view showing a configuration example of the detector 5 according to Embodiment 4.

FIG. 8C is a partially enlarged view of (b) of FIG. 8B.

FIG. 9A is a perspective view showing a configuration example of the detector 5 according to Embodiment 5.

FIG. 9B is a bottom view and a cross-sectional view showing a configuration example of the detector 5 according to Embodiment 5.

FIG. 9C shows a relationship between the light guide 11 and the light emitting element 10 according to Embodiment 5.

FIG. 10A is a perspective view showing a configuration example of the detector 5 according to Embodiment 6.

FIG. 10B is a bottom view showing a configuration example of the detector 5 according to Embodiment 6.

FIG. 11A is a perspective view showing a configuration example of the detector 5 according to Embodiment 7.

FIG. 11B is a bottom view and a cross-sectional view showing a configuration example of the detector 5 according to Embodiment 7.

FIG. 11C is a partially enlarged view of (b) of FIG. 11B.

FIG. 12A is a perspective view showing a three-dimensional structure of a detection element group 5g according to Embodiment 7.

FIG. 12B is a bottom view showing the three-dimensional structure of the detection element group 5g according to Embodiment 7.

FIG. 12C is a bottom view showing a configuration example of the detector 5 according to a modification of Embodiment 7.

FIG. 12D is a plan view showing a configuration example of the detector 5 according to a modification of Embodiment 7.

FIG. 12E is a perspective view showing a three-dimensional structure of the detection element group 5g according to a modification of Embodiment 7.

FIG. 13A shows a shape example of the light emitting element 10 according to Embodiment 7.

FIG. 13B shows a modified shape example of the light emitting element 10 according to Embodiment 7.

FIG. 14A is a perspective view showing a configuration example of the detector 5 according to Embodiment 8.

FIG. 14B is a bottom view and a cross-sectional view showing a configuration example of the detector 5 according to Embodiment 8.

FIG. 14C is a partially enlarged view of (b) of FIG. 14B.

FIG. 14D is a perspective view showing the detection element group 5g according to Embodiment 8.

FIG. 14E shows a structure example in the case of using a powder light emitting element.

FIG. 14F shows another structure example in the case of using a powder light emitting element.

FIG. 14G is a cross-sectional view showing the vicinity of an incident surface 10i according to a modification of Embodiment 8.

FIG. 15A is a view showing the detection element group 5g according to Embodiment 9.

FIG. 15B is a configuration example for creating a first image whose main signal source is X-rays using one detection element, and creating a second image whose main signal source is electrons using another detection element according to Embodiment 9.

FIG. 15C shows a configuration example in which a cross-sectional shape of the light guide 11 is curved according to Embodiment 9.

FIG. 15D shows a modification of Embodiment 1.

FIG. 15E shows a modification of Embodiment 2.

FIG. 16A shows a part of a detector according to Embodiment 10.

FIG. 16B shows a voltage signal Sv generated by a detection circuit 15 according to Embodiment 10.

FIG. 16C shows an example of a GUI according to Embodiment 10.

FIG. 17 shows a detector in the related art.

### DESCRIPTION OF EMBODIMENTS

Particles such as electrons and ions, photons, and radiation (high-energy photons) such as X-rays and gamma rays are collectively referred to as quanta. In the present specification, a quantum beam such as a particle beam of electrons or ions and X-rays or a gamma rays emitted to a sample is simply referred to as a beam, or quanta to be emitted are specified and referred to as an electron beam or the like for easy understanding. When a sample is irradiated with a beam, some quanta are emitted from the sample depending on energy and a type of the beam and a type of the sample. A light emitting element (generally referred to as a scintillator) is an element that emits light when quanta are incident thereon.

### Embodiment 1

Hereinafter, embodiments of the present disclosure will be described with reference to the drawings. Hereinafter, an electron microscope using an electron beam, in particular, a scanning electron microscope (SEM) will be described as an example of a charged particle beam apparatus, but the present disclosure is not limited thereto. For example, the charged particle beam apparatus includes a scanning ion microscope using an ion beam. It is needless to say that the present disclosure is also applicable to a semiconductor pattern measurement device, an inspection device, an observation device, and the like using a scanning electron microscope.

Embodiments of the present disclosure are not limited to embodiments to be described later, and various modifications can be made within the scope of the technical concept thereof. The same reference numerals may be given to corresponding portions in the drawings used in the description of the embodiments to be described later, and redundant description may be omitted.

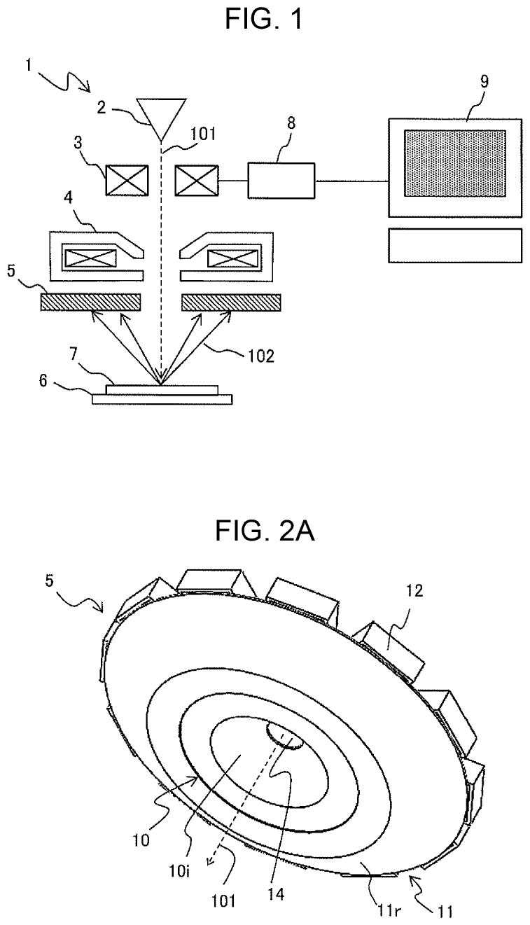

FIG. 1 is a schematic view showing an SEM which is a charged particle beam apparatus. The SEM functions as a measurement device. As shown in FIG. 1, the charged particle beam apparatus 1 includes a scanning deflector 3 and an objective lens 4 disposed on a trajectory of an electron beam 101 (generally referred to as primary electrons in the SEM) extracted from an electron source 2.

The electron beam 101 irradiates a sample 7 placed on a sample conveyance stage 6, and signal electrons 102 are emitted from the sample 7. Here, the signal electrons 102 refer to electrons emitted from the sample, such as secondary electrons directly excited by the electron beam 101 and emitted into vacuum, and reflected electrons emitted again into vacuum after the electron beam 101 is repeatedly scattered in the sample. In general, the reflected electrons are defined as signal electrons of 50 eV or more. When the sample 7 is irradiated with the electron beam 101, not only the signal electrons 102 but also X-rays may be generated. In the present embodiment, the signal electrons 102 are used as quanta incident on a detector, but the invention is not limited thereto, and a signal may be X-rays.

A detector 5 for detecting the signal electrons 102 is provided below the objective lens 4, and an opening is provided at the center of the detector 5 to allow the electron beam 101 to pass through the detector 5. The electron beam 101 emitted from the electron source 2 is controlled by the objective lens 4 and focused on the sample 7 so that a beam diameter is minimized. The scanning deflector 3 is controlled by a system control unit 8 so that a predetermined region of the sample 7 is scanned using the electron beam 101.

The signal electrons 102 generated from a position where the electron beam 101 reaches the sample 7 are detected by the detector 5. An SEM image is formed on a monitor 9 by performing signal processing on the detected signal electrons 102 in synchronization with a scanning signal transmitted from the system control unit 8 to the scanning deflector 3.

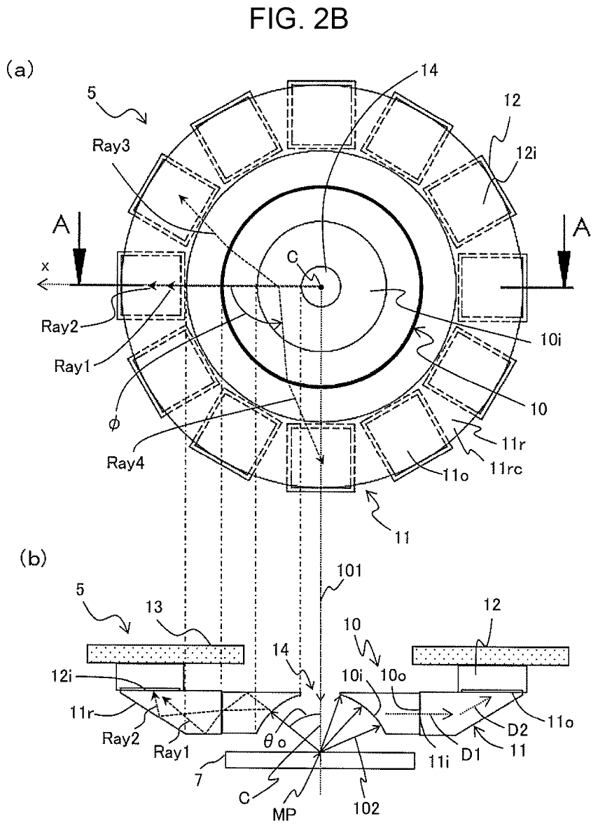

FIGS. 2A and 2B are views showing a configuration example of the detector 5. FIG. 2A is a perspective view, (a) of FIG. 2B is a bottom view showing the detector 5 as viewed from the sample 7, and (b) of FIG. 2B is a cross-sectional view taken along a line A-A of (a) of FIG. 2B.

In the description of the present embodiment, a direction away from a central axis C of an electron optical system of the charged particle beam apparatus (a radial direction, for example, an x-axis direction in (a) of FIG. 2B) is referred to as an outer side or an outer side direction, and a direction toward the central axis C is referred to as an inner side or an inner side direction.

The detector 5 includes a light emitting element 10, a light guide 11, light receiving elements 12, and a mounting substrate 13 on which the light receiving elements 12 are mounted. In (a) of FIG. 2B, a portion of the light receiving element 12 that is hidden by the light guide 11 and not visible is indicated by a broken line.

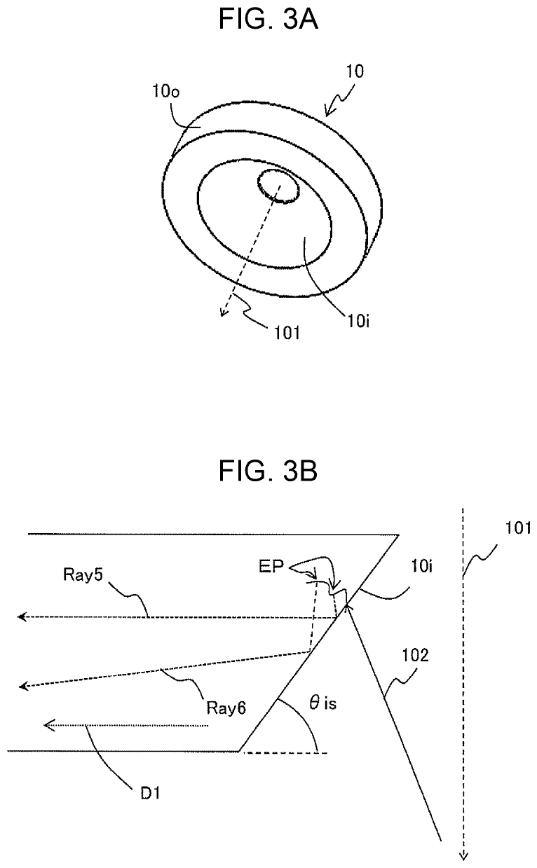

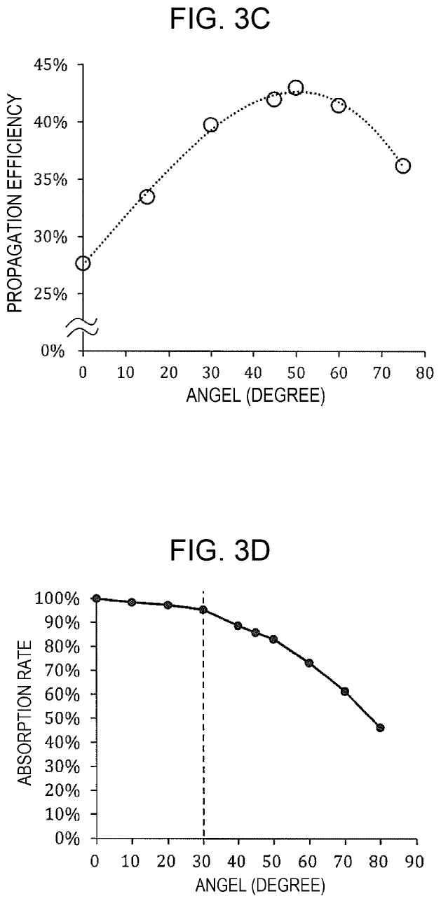

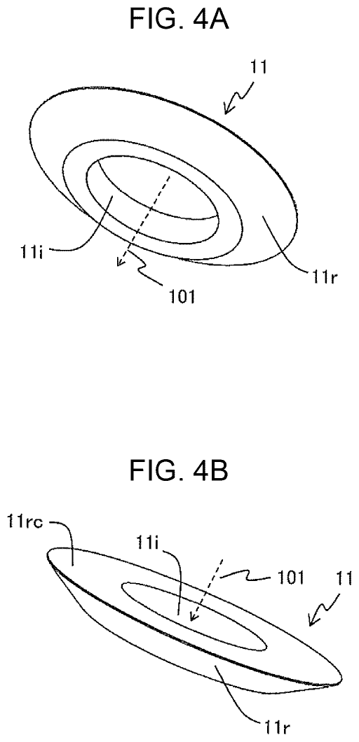

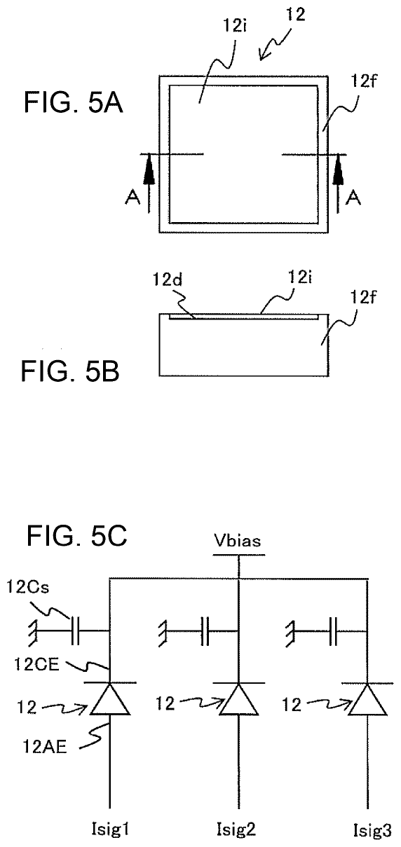

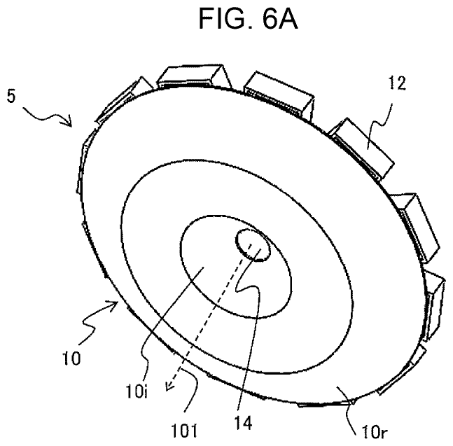

An outer shape of the light emitting element 10 is indicated by a thick line in (a) of FIG. 2B. FIG. 3A is a perspective view showing the light emitting element 10. FIGS. 4A and 4B are perspective views showing the light guide 11. FIG. 5 is a detailed view showing the light receiving element 12.

In the present embodiment, a case where an SiPM is used will be described, the SiPM being a light receiving element having a smallest gain in the 106 class. However, the light receiving element is not limited thereto. Various light receiving elements such as a PMT (for example, a micro PMT which is a small PMT), an avalanche photodiode, and a PIN photodiode can be used.

The center of the detector 5 for allowing the electron beam 101 to pass through is formed as an opening 14, and a hole is formed in the mounting substrate 13, which is a region where there is no member such as the light emitting element 10. The electron beam 101 passes through the opening 14 and is incident on the sample 7.

A process from when the sample 7 is irradiated with the electron beam 101 to reception of photons of the signal electrons 102 will be described with reference to (b) of FIG. 2B. (b) of FIG. 2B shows the sample 7, the electron beam 101, the signal electrons 102, and light rays Ray 1 and Ray 2 generated by the light emitting element.

The signal electrons 102 are emitted from an observation point MP where the electron beam 101 is incident on the sample 7. Since the electron beam 101 is used to scan the sample 7, strictly speaking, the observation point MP moves in a certain range, but since the range is sufficiently small as compared with a size of the detector, it is assumed that the observation point MP is an intersection point between the central axis C and the sample 7 as shown in (b) of FIG. 2B in the description of the present embodiment.

An angle (a polar angle θo) between a direction in which the signal electrons 102 fly and the central axis C may be considered to approximately remain as an emission angle at which the signal electrons 102 are emitted from the observation point MP when the signal electrons 102 are reflected electrons having high energy. Hereinafter, an angle from the central axis C is defined as a polar angle, and an angle in a plane perpendicular to the central axis C is defined as an azimuth angle φ. A reference of the azimuth angle is set as appropriate if necessary.

Most of the signal electrons 102 emitted from the sample 7 are incident on an incident surface 10i of the light emitting element, enter an inner side from the incident surface 10i by several tens nm to several tens μm depending on energy of the electrons, which causes an energy loss. On the other hand, the light emitting element 10 that obtained the energy emits light. Therefore, a light emitting region is a thin shell-shaped region of about several tens of μm from the incident surface 10i. When the signal electrons 102 having high energy generated by increasing a current of the electron beam 101 or increasing a voltage for accelerating the electron beam are incident on the incident surface 10i, a large number of photons are generated from the thin shell-shaped region.

As described above, the light emitting element 10 emits light due to collision of quanta (which is the signal electron 102 in the present embodiment, but may be another particle beam or radiation, and the same applies to other embodiments) emitted from the sample 7 by irradiating the sample 7 with a beam (the electron beam 101 in the present embodiment, but is not limited thereto).

Here, a problem caused by a large number of photons generated from a minute region will be described using an example of a detector in the related art as shown in FIG. 17.

In the case of a detector disposed between the sample 7 and the objective lens of the SEM, a space from the mounting substrate 13 to the sample 7 is about 5 mm in order to obtain sufficient performance with resolution of the SEM or the like. Therefore, there is almost no room for a light guide, and as shown in FIG. 17, the light receiving element 12 is disposed on the mounting substrate, and the light emitting element 10 is disposed to face the light receiving element 12. In this case, a distance between the observation point MP and an innermost light emitting element 10n is about 1 mm to 3 mm.

On the other hand, since the SiPM is small and has a size of about 3 mm, most of the signal electrons 102 are concentrated on the light emitting element 10n closest to the electron beam 101, and a light receiving element 12n saturates. With such a configuration, when the light receiving element is an SiPM, a current value of the electron beam saturates at about several tens of pA. On the other hand, in order to obtain an SEM image with a sufficient S/N, depending on the sample 7, a current of several nA or more is required in a semiconductor circuit pattern having a three-dimensional structure such as a trench portion.

In order to solve this problem, a configuration shown in FIGS. 2A to 5 is adopted the present embodiment, in which most of the light generated in a large amount on the incident surface 10i is guided in a first direction intersecting an irradiation direction of the electron beam 101, and the light propagates in the first direction through an optical system including the light emitting element 10 and the light guide 11 to diffuse the light and reduce a photon density. The first direction is, for example, roughly a direction from the electron beam 101 toward an outer side in the radial direction, and may include a component in an axial direction of the electron beam 101 (the same direction as a traveling direction of the electron beam 101 or an opposite direction thereto). An optical path that guides light in the first direction is referred to as a first optical path.

A second optical path that guides light from the first optical path toward a light receiving surface of the light receiving element continues at a position where the light is diffused to some extent, and the light reaches the light receiving element. In this manner, the detector 5 forms the first optical path and the second optical path. The first optical path is an optical path that guides light in the first direction, and the second optical path is an optical path that guides light arriving via the first optical path toward a light receiving surface 12i (see (a) of FIG. 2B) of the light receiving element 12.

As shown in (a) of FIG. 2B, the light receiving element 12 includes the light receiving surface 12i, and light generated by the light emitting element 10 is received by the light receiving surface 12i. In the present embodiment, by disposing the light receiving surface 12i at a position farther from the electron beam 101 than the light emitting element 10, the electron beam 101 can be surrounded by a large number of light receiving elements 12, and diffused light can be received. With such a configuration, saturation of a signal of the light receiving element 12 is prevented.

In the present embodiment, the light receiving element 12 can be a silicon photomultiplier. In this manner, the saturation of the signal can be prevented according to characteristics of the silicon photomultiplier.

A position where the light receiving surface is farther from the electron beam than the light emitting element refers to, for example, in a certain definition example, a configuration in which a distance between the electron beam and a portion of the light receiving surface closest to the electron beam is larger than a distance between the electron beam and a portion of the light emitting element closest to the electron beam. In another definition example, the position refers to a configuration in which a distance between the electron beam and a portion of the light receiving surface farthest from the electron beam is larger than a distance between the electron beam and a portion of the light emitting element farthest from the electron beam. A definition obtained by combining these two definition conditions may be used. In (b) of FIG. 2B, all portions of the light receiving surface 12i are positioned farther from the electron beam 101 than all portions of the light emitting element 10.

In the present embodiment, the light receiving surface 12i is disposed in a direction orthogonal to an irradiation direction of the electron beam 101 (that is, a normal line of the light receiving surface 12i is parallel to the irradiation direction of the electron beam 101). Therefore, the detector 5 can be configured to be thinned (that is, an axial dimension can be reduced). The light receiving surface 12i is not limited to be disposed in a direction strictly orthogonal to the irradiation direction of the electron beam 101, and as long as the direction intersects the irradiation direction of the electron beam 101, the axial dimension of the detector 5 can be reduced to an extent corresponding to the direction.

An emission surface 10o of the light emitting element 10 and an incident surface 11i of the light guide 11 are bonded to each other, and an emission surface 11o of the light guide 11 and the light receiving surface 12i of the light receiving element 12 are bonded to each other.

The light emitting element 10, the light guide 11, and the light receiving element 12 are mounted on the same mounting substrate 13. As shown in (b) of FIG. 2B, a structure in which the light guide 11 forms the first optical path and the second optical path enables light to propagate from the light emitting element 10 to the light receiving element 12 that are mounted on the same substrate. As a result of mounting the light emitting element 10 and the light receiving element 12 on the same substrate, a length of the light guide 11 can be shortened as compared with a case where the light guide 10 and the light receiving element 12 are mounted on different substrates, and a structure with high light utilization efficiency can be obtained.

As shown in (b) of FIG. 2B, a length of the light guide 11 in the first direction in a cross section including the central axis C can be made shorter than a width of two light receiving elements 12. When the size of the light guide 11 can be reduced, the entire detector 5 can be reduced in size, so that the light guide 11 can be placed in various installation places and an application range is widened. Although the light emitting element 10 and the light guide 11 are fixed by adhesion, a fixing method is not limited thereto, and the light emitting element 10 and the light guide 11 may be mechanically fixed to the mounting substrate 13 by covering with a thin cover or using a screw or the like, or both the adhesion and the mechanical fixing may be used.

A most preferable arrangement of the light receiving elements 12 surrounding the electron beam 101 in (a) of FIG. 2B is a circle (for example, each vertex of a regular polygon) because light can be uniformly received. In addition, since the circular arrangement allows the light receiving elements to be arranged at high density, it is possible to cope with an increase in current, and since the light receiving elements can efficiently receive propagating light without loss, it is possible to improve light utilization efficiency. However, the shape is not necessarily a circle, and there are various surrounding methods such as a quadrangle and an ellipse in which intervals of the light receiving elements 12 are random, and the invention is not limited by an arrangement method of the light receiving elements 12.

In the example of (b) of FIG. 2B, the first direction can be defined as a direction orthogonal to the electron beam 101, for example, a direction of an arrow D1. Although it is orthogonal in this example, the mounting substrate 13 may be inclined due to mounting in the SEM or the electron beam 101 may be inclined depending on a measurement target, and the first direction can be appropriately set. It is important to diffuse light in a direction not parallel to the electron beam 101 (a direction intersecting the electron beam 101).

An example of a configuration for guiding light in the first direction is a configuration in which the light emitting element 10 and the light guide 11 are arranged in the first direction in a cross section including the central axis C as shown in (b) of FIG. 2B, and an optical path formed by the light emitting element 10 and the light guide 11 is the first optical path. Since the incident surface 10i of the light emitting element is a spherical surface, the incident surface 10i is a surface that reflects and guides, in the first direction, a part of light isotropically emitted inside the light emitting element.

In (b) of FIG. 2B, the second optical path is a radially outer portion of the light guide, that is, a triangular region having a reflection surface 11r, which is a region indicated by an arrow D2. Since light traveling toward the light receiving surface 12i rapidly increases toward an outer side in the radial direction from a point where the reflection surface 11r having an inclination relative to the first direction starts, an optical path after a position where the reflection surface 11r starts can be referred to as the second optical path. Similarly, when the first optical path and the second optical path are formed by curved surfaces, a position where light traveling toward the light receiving surface 12i starts to increase or a position after a position where the inclination of a surface relative to the first optical path increases can be set as the second optical path.

A boundary between the first optical path and the second optical path may or may not be clearly defined. A downstream portion of the first optical path and an upstream portion of the second optical path may overlap each other, or another optical path may be formed between the first optical path and the second optical path. For example, a portion including an optical path immediately after light is generated by the light emitting element 10 is the first optical path, and a portion including an optical path immediately before light is incident on the light receiving surface 12i of the light receiving element 12 is the second optical path.

The light rays Ray 1 and Ray 2 will be described in detail. Both of the light rays emit light at a point where the signal electrons 102 are incident and start to propagate. The light ray Ray 1 is not reflected by the reflection surface 11r, but propagates through the first optical path, then propagates through the second optical path, and is incident on the light receiving element. The light receiving surface 12i and the emission surface 11o of the light guide are coupled by an adhesive, and the light ray Ray 1 is incident on the light receiving surface 12i via the adhesive without being reflected by the emission surface 11o.

In particular, the light ray Ray 1 is reflected twice in the first optical path. In this manner, the first optical path is formed to include surfaces that perform the following reflection.
a surface that reflects light, which includes a component in the first direction and a component in a direction opposite to the irradiation direction of the electron beam (an upward component in the drawing), in a direction including a component in the first direction and a component in the irradiation direction of the electron beam (a downward component in the drawing) (first reflection)
a surface that reflects light, which includes a component in the first direction and a component in the irradiation direction of the electron beam (a downward component in the drawing), in a direction including a component in the first direction and a component in a direction opposite to the irradiation direction of the electron beam (an upward component in the drawing) (second reflection)

Light can be propagated in the first direction by adopting a configuration in which the first optical path includes at least one of such surfaces.

The light ray Ray 2 travels substantially straight in the first direction, is reflected by the reflection surface 11r in the second optical path, and is incident on the light receiving element. For example, the reflection surface 11r is a surface that reflects light, which arrives at the reflection surface 11r in a direction orthogonal to the irradiation direction of the electron beam (the light ray Ray 2 roughly arrives in this direction), in a direction having a component in a direction opposite to the irradiation direction of the electron beam (an upward component in the drawing). According to such a configuration, the light traveling in the first direction can be guided to the light receiving surface 12i.

The reflection at an interface between the light emitting element 10 and the vacuum of the light guide 11 is assumed to be total reflection. Therefore, light that does not satisfy a total reflection condition is emitted into vacuum and causes a loss. In order to reduce the loss, a reflective material such as an aluminum film may be formed on surfaces of these members. In addition, when there is no adhesive between the light receiving surface 12i and the emission surface 11o of the light guide and there is air in an interface with the light guide, a probability of reflection at the emission surface 11o due to total reflection or Fresnel reflection is high.

For example, a probability that the light ray Ray 1 or the like is reflected is high since an incident angle on the emission surface 11o is large, and the light reflected by the emission surface 11o may be repeatedly reflected between the reflection surface 11r and the light receiving surface 12i and then incident on the light receiving surface 12i, or may be emitted from the reflection surface 11r to the outside of the detector or become stray light, which causes a light loss. Therefore, it is preferable to provide an adhesive between the light receiving surface 12i and the emission surface 11o of the light guide.

The spread of light in an azimuth angle φ direction in (a) of FIG. 2B will be described using light rays Ray 1 to Ray 4. For convenience, a position in a circumferential direction of a point where the signal electrons 102 are incident is used as a reference of the azimuth angle φ and is defined as an x axis. The light ray Ray 1 and the light ray Ray 2 in (a) of FIG. 2B are light ray examples having the azimuth angle φ of zero and are incident on the light receiving element 12 closest to the point where the signal electrons 102 are incident.

Since light emission in an azimuth angle direction is isotropic, the light propagates in a direction with a large azimuth angle such as the light ray Ray 3 and the light ray Ray 4. Accordingly, the light is diffused by propagating in various azimuth angle directions.

As described above, when the light receiving elements 12 are arranged in a manner of surrounding the electron beam 101 as in the present embodiment, the light receiving elements 12 can receive the light diffused in the azimuth angle direction. That is, the present configuration, in which the light emitting element 10 is disposed at the center in a manner of surrounding the central axis, the light receiving elements 12 are disposed at an outer periphery in a manner of surrounding the central axis, and light propagates in the first direction and then propagates in the second direction, is a configuration in which light emitted in a minute region near the center is diffused in the azimuth angle direction to reduce a density of photons, and the light is received by the plurality of light receiving elements 12 in the surrounding, thereby reducing the amount of light entering one light receiving element and preventing saturation. By increasing the circumference of the light receiving elements 12 according to an amount of the electron beam 101, it is possible to provide a detector without saturation even when the amount of the signal electrons 102 increase.

The outline of the present embodiment was described above. Hereinafter, each member will be described in detail.

The light emitting element 10 according to the present embodiment is a crystal light emitting element whose shape can be changed by cutting or the like. Examples of materials of the light emitting element include YAP (YAlO₃: Ce), YSO (Y₂SiO₅: Ce), YAG (Y₃Al₅O₁₂: Ce), GGAG ((Y, Gd)₃(Al, Ga)₅O₁₂: Ce, (Y, Gd)₃(Al, Ga)₅O₁₂: Tb), GOS (Gd₂O₂S: Pr, Gd₂O₂S: Ce, Gd₂O₂S: Tb). The crystal may be a single crystal, a polycrystal, or a sintered ceramic. However, the invention is not limited by the material of the light emitting element.

As shown in (b) of FIG. 2B and FIG. 3A, a shape of the incident surface 10i is a spherical surface centered on the observation point MP. This is because a normal line of the surface is directed toward the observation point MP. There are two advantages of such a configuration. One is a point where the spherically emitted light is reflected in the first direction as described above. The other is to absorb energy of the incident signal electrons as much as possible to increase an amount of emitted light. This will be described sequentially.

The reflection in the first direction is effective when the incident surface 10i is inclined relative to the first direction. For the sake of simplicity, a case of the incident surface 10i inclined at a certain angle relative to the first direction will be considered.

FIG. 3B is an enlarged view showing the vicinity of a position where the signal electrons 102 are incident. The incident surface 10i is inclined at an inclination angle θis. For example, the signal electrons 102 enter an inner side of the light emitting element 10 by about several tens of μm at the maximum while being scattered.

Inside the light emitting element, light is emitted due to excitation of an energy state caused by receiving energy from the signal electrons 102, thereby emitting energy. The emitted light is isotropically emitted from each light emitting point. As indicated by a light ray Ray 5 and a light ray Ray 6 in FIG. 3B, a part of light emitted at a plurality of light emitting points EP inside the light emitting element propagates toward the incident surface 10i, is reflected by the inclined incident surface 10i, and propagates roughly in the first direction (a direction of an arrow D1). As described above, when the incident surface 10i of the light emitting element on which the signal electrons 102 are incident is inclined relative to the first direction, there is an effect that light is reflected in a direction having a component in the first direction.

FIG. 3C shows a result of examining this effect by light ray tracing simulation. In an optical system in which the light emitting element 10 having a cross-sectional shape shown in FIG. 3B and having a refractive index of about 2.0 and the light guide 11 having a refractive index of about 1.5 are coupled by an adhesive having a refractive index of about 1.5, propagation efficiency of photons reaching the incident surface of the light guide (an amount of light reaching the incident surface of the light guide/an amount of emitted light) was calculated.

In FIG. 3C, a vertical axis represents propagation efficiency, and a horizontal axis represents the inclination angle θis. According to this result, a light amount is maximized when the inclination angle θis is about 45 degrees to 50 degrees. When the inclination angle is 45 degrees, the light amount is about 1.6 times light amount compared when the inclination angle is 0 degrees. On the other hand, when the inclination angle is less than 15 degrees or 80 degrees or more, the effect is reduced (an improvement rate obtained by the inclination is less than half of a maximum improvement rate). Therefore, from the viewpoint of propagation efficiency, the inclination angle is preferably 15 degrees or more and less than 80 degrees.

Although the incident surface 10i is inclined relative to the first direction in the present embodiment, reflection by a surface other than the incident surface 10i may be used when only an effect of reflection in the first direction is considered. For example, when the incident surface 10i is parallel to the first direction, the same effect can also be obtained by inclining, relative to the first direction, a surface facing the incident surface 10i in a beam irradiation direction (a surface opposite to the incident surface 10i). That is, when the shape of the light emitting element in FIG. 3B is inverted vertically (that is, with respect to the beam irradiation direction) and a lower plane after the inversion is used as the incident surface, the same effect by reflection can also be obtained.

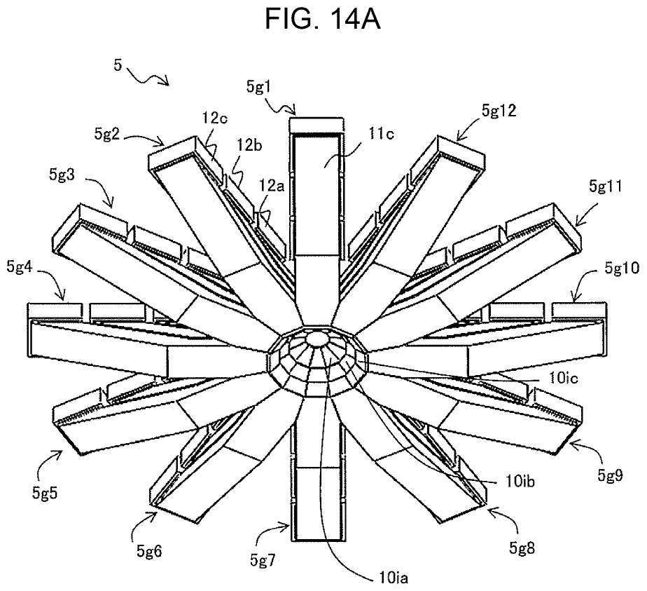

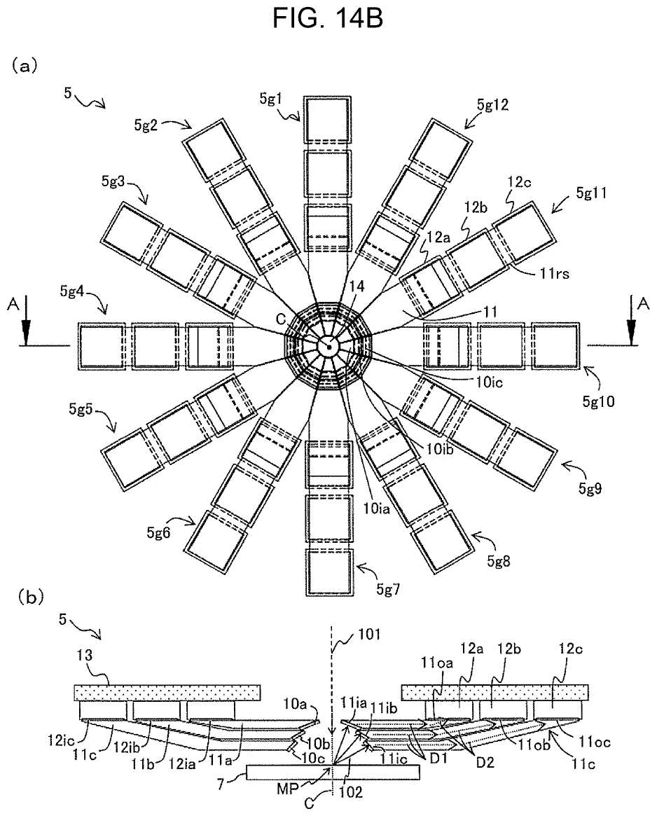

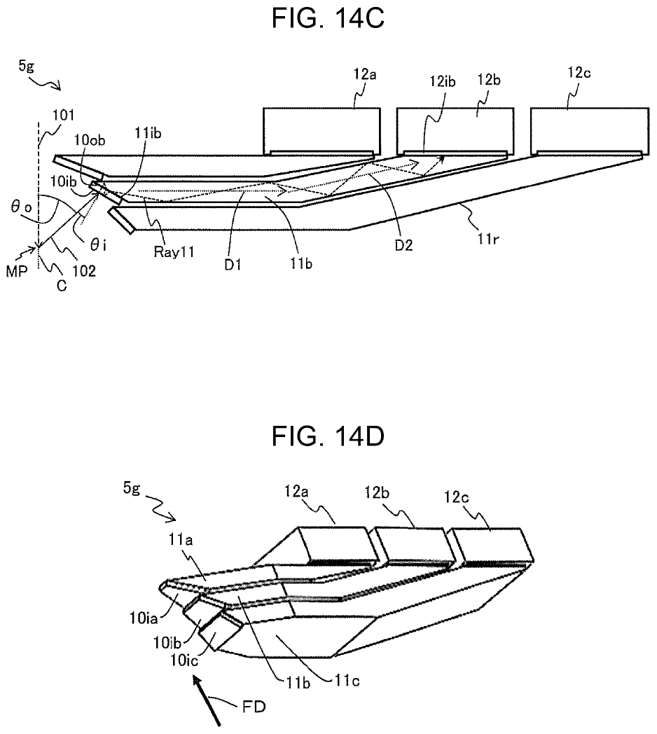

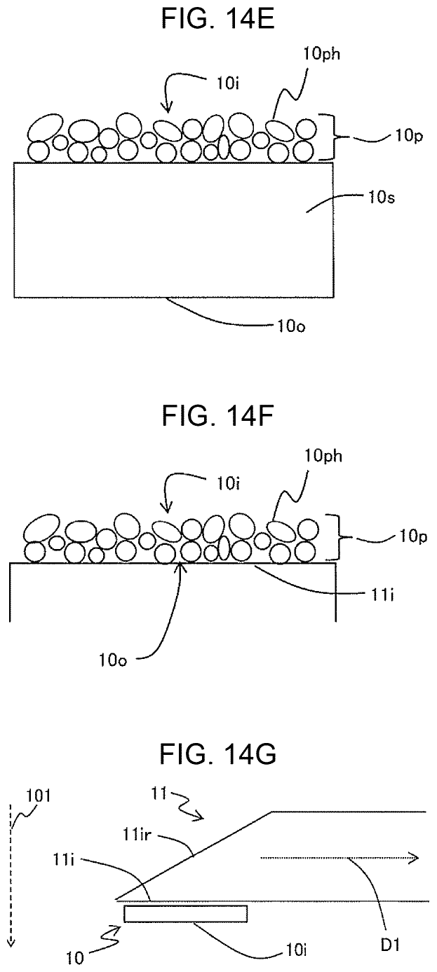

An example in which only the effect of such reflection is considered will be described according to Embodiment 8 (see FIG. 14G). Both the incident surface 10i and a surface opposite to the incident surface 10i may be inclined relative to the first direction.

Next, an advantage of sufficiently absorbing energy of signal electrons to increase an amount of emitted light will be described. When the incident surface 10i is a spherical surface, an angle (an incident angle) at which the signal electrons 102 emitted from the observation point MP are incident on the incident surface 10i is zero, and an amount of emitted light obtained from one signal electron is maximized. This is because when the incident angle increases, signal electrons once incident on the light emitting element are repeatedly scattered in the light emitting element and escape from the light emitting element into vacuum again. This mechanism is a conclusion obtained from experiments and electron trajectory simulation.

FIG. 3D shows a relationship between an incident angle on the light emitting element and an amount of signal electrons absorbed in the light emitting element without escaping. A horizontal axis represents an incident angle θi, and a vertical axis represents a relative signal electron absorption amount with reference to 0 degrees.

An absorption rate is maximum when the incident angle θi is zero, and drops sharply when the incident angle θi exceeds 30 degrees. That is, when the incident angle θi of the signal electrons on the light emitting element exceeds 30 degrees, a reduction in the amount of emitted light increases. Therefore, by arranging the light emitting element such that the incident angle θi is 30 degrees or less, there is an effect of preventing a reduction in the amount of emitted light. From this viewpoint, the spherical surface is a preferable shape since the incident angle θi is smallest. Further, since the incident surface 10i having the incident angle θi less than 30 degrees can be easily designed as a surface inclined relative to the first direction, the configuration in the present embodiment can obtain both advantages.

Here, the incident surface 10i can be configured to have an incident angle θi of 30 degrees or less, such as a spherical surface, because, as shown in (a) of FIG. 2B, the light receiving element 12 is disposed at a position farther from the electron beam 101 than the light emitting element 10 and is coupled to the light emitting element 10 by the light guide 11, and a position where the signal electrons are detected in a minute region and a position where the emitted light is received are separated from each other. That is, even when the incident surface 10i of the light emitting element has a free shape, an effect of the light emitting element 10 and the light guide 11 extending in the first direction are cancelled by the shape (an influence of a shape difference from the light receiving surface 12i), and the emitted light can be efficiently propagated to the light receiving surface 12i.

Next, the light guide 11 will be described with reference to FIGS. 2A, 2B, 4A, and 4B. FIGS. 4A and 4B are perspective views showing the light guide 11 as viewed from the sample 7 and viewed from a side irradiated with the electron beam, respectively, and are views showing a three-dimensional shape. FIG. 4A shows the reflection surface 11r and the incident surface 11i facing the emission surface 10o of the light emitting element. The incident surface 11i has a cylindrical shape because the emission surface 10o of the light emitting element has a cylindrical shape.

FIG. 4B shows a surface 11rc opposite to the reflection surface 11r, and a surface facing the light receiving surface 12i of the light receiving element in the plane is the emission surface 11o (see the bottom view in (a) of FIG. 2B).

In the present embodiment, the light guide 11 is fixed to the mounting substrate 13 by adhering the light guide 11 to the light receiving surface 12i with an adhesive having a refractive index close to that of a material of the light guide 11 and fixing the light guide 11 via the light receiving element 12. Although mechanical fixing using screws or the like may be used, the light utilization efficiency is improved by fixing with an adhesive.

Light reaching the emission surface 11o is reflected and does not enter the light receiving element when an incident angle on the emission surface is equal to or larger than total reflection, and most of the light becomes stray light, which causes a light loss. When the light guide 11 is made of resin or quartz, since the refractive index is about 1.5, light having an incident angle of 42 degrees or more is totally reflected. However, when a resin or glass adhesive having a similar refractive index is used, total reflection does not occur between the light guide 11 and the adhesive, and most of the light reaching the emission surface 11o is incident on the light receiving surface 12i. Therefore, the adhesive having substantially the same refractive index serves as a member for extracting light from the light guide 11 to the light receiving element 12.

The refractive index of the adhesive is preferably equal to or larger than the refractive index of the light guide 11 and equal to or smaller than the refractive index of the light receiving surface from the viewpoint of total reflection. For example, the light receiving surface and the adhesive are preferably made of epoxy resin (having a refractive index of about 1.55), and the light guide 11 is preferably made of acrylic resin (having a refractive index of about 1.49) from the viewpoint of transparency.

The adhesive serving as a light extraction member is preferably applied in a manner of covering the entire light receiving surface 12i indicated by a broken line in (a) of FIG. 2B. By using such an adhesive, on the surface 11rc opposite to the reflection surface 11r, a transmittance of light emitted to the outside of the light guide increases only on the emission surface 11o facing the light receiving surface 12i, and an amount of light received on the light receiving surface 12i increases, and a loss amount of light emitted from a surface of the surface 11rc that does not face the light receiving surface 12i into vacuum is reduced accordingly.

An increase in the transmittance to the light receiving surface 12i only on the emission surface 11o also increases a probability that light propagating toward a position other than the light receiving surface 12i in the azimuth angle direction is repeatedly scattered and incident on the light receiving surface 12i. That is, the light utilization efficiency of light emitted in a direction other than the light receiving surface 12i in the azimuth angle direction is also improved.

However, a member other than the adhesive may be used as the light extraction member. A gel-like member may be interposed between the light guide 11 and the light receiving surface 12i, or a light extraction structure in which the emission surface 11o facing the light receiving surface 12i is a minute structure surface such as a rough surface or an uneven surface may be provided. Even in such cases, an effect of improving the light utilization efficiency can be obtained. A light extraction member such as an adhesive and a light extraction structure may be used in combination.

On the other hand, it is preferable to use an adhesive for fixing the light guide 11 and the light emitting element 10 because the adhesive improves the light utilization efficiency for the same reason of preventing total reflection. That is, the adhesive also functions as a member that guides light from the light emitting element 10 to the light guide 11 and guides light in the first direction.

Since the refractive index of the light emitting element such as a material of the light emitting element described above is generally larger than about 2.0, the refractive index of the light guide 11 generally made of a quartz or resin material is smaller. Therefore, total reflection occurs at an interface between the light emitting element and the adhesive. This total reflection causes a phenomenon in which emitted light is confined in the light emitting element, and the light is repeatedly scattered until the emitted light is absorbed by the light emitting element or a reflective material such as aluminum.

This loss depends on a shape of the light emitting element and the presence or absence of a light extraction member such as an adhesive, and 70 percent to 80 percent of emitted light may be lost. In order to extract the confined light to the outside, in the repeated scattering, an incident angle at an interface with a bonding surface may be set within a total reflection angle.

Since the total reflection angle at the interface with the vacuum of the light emitting element having a refractive index of 2.0 is 30 degrees, whereas the total reflection angle at an interface with the adhesive having a refractive index of 1.5 is 48 degrees, an incident angle on the bonding surface may be within 48 degrees in some structures.

In a cross-sectional shape of the light emitting element shown in FIG. 3B, in the case of a quadrangle in which the inclination angle θis of the incident surface 10i is 0 degrees, the incident angle of totally reflected light does not change on four surfaces of upper, lower, left, and right, and the total reflection is repeated until the light is absorbed. However, when the inclination angle θis is an angle other than an angle of 0 degrees, for light incident on and reflected by the incident surface 10i, an incident angle on a next surface is changed. By changing the incident angle, the confined light is incident, within the total reflection angle, on an interface with an adhesive material that is most likely to emit light, passes through the adhesive, and is incident on the light guide 11, so that the light utilization efficiency is improved.

That is, both the fixation of the light emitting element and the light guide by an adhesive and the inclination of the incident surface 10i of the light emitting element obtain an effect of efficiently extracting confined light, for which is total reflection is repeatedly performed, from the light emitting element using the light guide.

In addition, when the incident surface 10i has an inclination, a triple effect is achieved by combining an effect of changing a propagation angle as in the case of the light ray Ray 5 and the light ray Ray6 described above and an effect of improving an absorption amount of the signal electrons 102. Therefore, it can be seen that a preferable effect is obtained when the incident surface 10i is an inclined surface.

The SiPM serving as the light receiving element will be described with reference to FIG. 5. (a) of FIG. 5 is a bottom view showing the SiPM as viewed from the light receiving surface 12i, and (b) of FIG. 5 is a cross-sectional view taken along a line A-A in (a) of FIG. 5. (c) of FIG. 5 is a diagram showing an example of a circuit for obtaining a signal from the SiPM.

A detection surface 12d that converts light into an electrical signal is provided in a frame 12f, and a transparent resin, a quartz cover, or the like is provided to protect the detection surface 12d. In the present embodiment, the light receiving surface 12i is a resin or quartz surface facing the detection surface 12d.

In the case of the SiPM, a dynamic range is maximized when the detection surface 12d is irradiated with uniform light, and saturation can be prevented. Therefore, since the reflection surface 11r of the light guide reflects the light to the entire light receiving surface 12i as in the present embodiment, the light receiving surface 12i is not partially covered but totally covered. With such a configuration, the effect of preventing saturation is obtained.

The SiPM has an anode electrode and a cathode electrode, a high voltage is applied to the cathode electrode, and a current value output from the anode electrode is read and used as a signal. Such a circuit example will be described in the present embodiment, and other circuit examples can be considered.

When a plurality of SiPMs are provided, there is a problem that the number of wires increases. On the other hand, the voltage applied to the cathode electrode is a voltage for controlling the magnitude of the electrical signal output from the SiPM, and determines a multiplication rate defined by the number of electrons generated in the SiPM when one photon is detected.

In general, since a voltage for obtaining the same multiplication rate varies for each individual SiPM, it is necessary to individually control the voltage. However, when an individual SiPM is appropriately selected, the voltage for obtaining the same multiplication rate can be reduced to, for example, 0.5 V or less, and operating voltages applied to electrodes of a plurality of SiPMs can be made the same (for example, wires can be shared). For example, the number of wires can be reduced by half by applying a common voltage to all SiPMs.

However, by selecting an individual SiPM only, even when the number of photons is the same, a current value output from the SiPMs may be different and an SEM image may be affected. Regarding this influence, it is preferable to adjust and reduce the influence for each SiPM by a circuit or signal processing in a subsequent stage.

(c) of FIG. 5 shows an example of the circuit. For simplicity, a case where the number of SiPMs serving as the light receiving elements 12 is three is shown. As described above, it is preferable that each SiPM includes an anode electrode 12AE and a cathode electrode 12CE, current signals Isig 1 to Isig 3 are output from the anode electrodes 12AE, and the current signals Isig 1 to Isig 3 are individually read and subjected to signal processing. It is needless to say that, when the influence is small, the SiPMs may be connected and the sum of currents may be read, and an appropriate configuration may be adopted.

A bias voltage Vbias is applied to the cathode electrode 12CE as an operating voltage for determining a multiplication rate. Further, in order to prevent a fluctuation of the operating voltage applied to the cathode electrode 12CE, a capacitor 12Cs may be connected on the same mounting substrate 13.

In (c) of FIG. 5, the cathode electrodes 12CE of all the SiPMs are connected to wires for supplying the bias voltage Vbias to make the voltage applied to the SiPMs come to be common, thereby reducing the number of wires to one. When the bias voltage Vbias is individually provided in the case of three SiPMs, a total of three wires are required for the cathode electrodes 12CE, and two wires can be reduced by making the voltages applied to the SiPMs come to be common. A configuration in which the number of wires can be reduced is suitable for a configuration in which the scale of a connector or the like is reduced and a detector is installed in a narrow portion as in the present embodiment.

Although a circuit component such as a resistor may be interposed between the cathode electrode 12CE and a wire for supplying the bias voltage Vbias for noise prevention or the like, there is no problem as long as voltages fall within a range that can be regarded as the same operating voltage. An example of the range may be a range in which a signal output from the anode electrode 12AE can be corrected by the signal processing (for example, a range in which there is no saturation in a subsequent circuit). It is preferable that the operating voltage applied to the cathode electrode 12CE is within a range of ±10% from a predetermined voltage. For example, when the predetermined operating voltage Vbias is 55 V, the operating voltage may fall within a range of about 50 to 60 V.

From another point of view, this configuration can be referred to as a configuration in which a certain wire branches and is connected to the plurality of cathode electrodes 12CE on the mounting substrate 13 to reduce the number of wires.

By disposing the light receiving surface 12i of the light receiving element at a position farther from the electron beam 101 than the light emitting element 10 in the first direction, a position of the light emitting element 10 and a position of the light receiving element 12 are separated from each other in the first direction. Accordingly, a space in which light is diffused is formed between the light emitting element 10 and the light receiving element 12, and an effect of increasing a current is achieved.

At the same time, the light emitting element 10 can be extended in the first direction by being separated from the light receiving element 12 in the first direction. Accordingly, the incident surface 10i and the emission surface 10o can have completely different shapes. As a result, the shape of the incident surface 10i may be a spherical surface to efficiently detect signal electrons, and the shape of the emission surface 10o may be a shape in which a normal line of the surface is substantially parallel to the first direction (the arrow D1) to easily emit light in the first direction. That is, the separation in the first direction described above has an effect of efficiently detecting signal electrons and facilitating light emission in the first direction (improvement in the light utilization efficiency).

Further, after the light propagates in the first direction in the first optical path, the light arriving via the first optical path propagates toward the light receiving surface 12i using a reflection surface or the like, so that it is possible to uniformly emit the light to the light receiving surface 12i having a larger area than the emission surface 10o of the light emitting element. That is, a difference in area between the emission surface 10o and the light receiving surface 12i is eliminated in the second optical path.

In general, by disposing the light receiving surface 12i of the light receiving element at a position farther from the electron beam 101 than the light emitting element 10 in the first direction, after light propagates in the first direction, the light propagates light in the second optical path toward the light receiving surface 12i using the reflection surface or the like, so that effects of increasing the current of the electron beam 101, detecting the signal electrons with high efficiency, improving the light utilization efficiency, and uniformly light incident on the light receiving surface are obtained at the same time.

### Embodiment 2

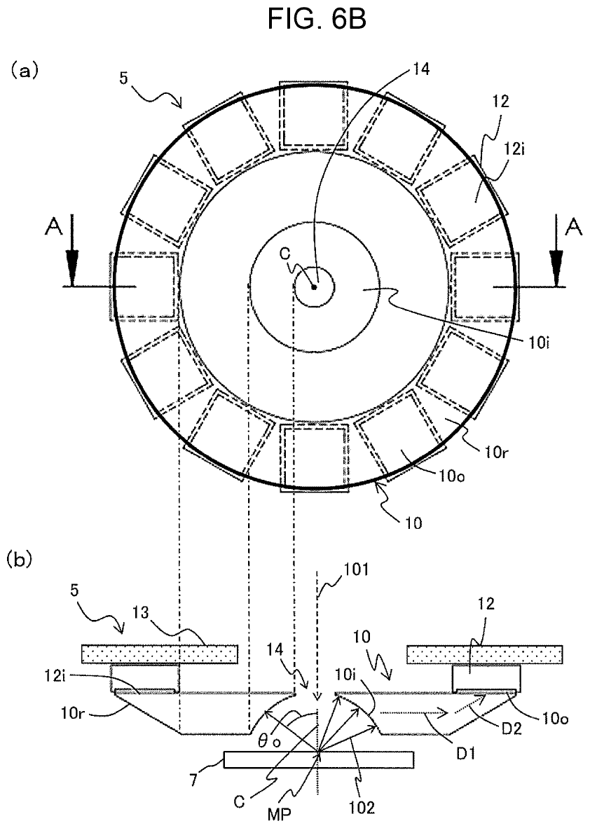

FIGS. 6A and 6B are views showing a configuration example of the detector 5 according to Embodiment 2. FIG. 6A is a perspective view. (a) of FIG. 6B is a bottom view. (b) of FIG. 6B is a cross-sectional view taken along a line A-A in (a) of FIG. 6B. Description of the same configuration as that of Embodiment 1 will be omitted. A difference from Embodiment 1 is that the light emitting element 10 functions as the light guide 11.

As can be seen from a comparison between (b) of FIG. 2B and (b) of FIG. 6B, the light emitting element 10 according to Embodiment 2 has a shape in which the light emitting element 10 and the light guide 11 according to Embodiment 1 are combined. In FIGS. 2A and 2B, the first optical path (an optical path that guides light in a direction of an arrow D1) formed by the light emitting element 10 and the light guide 11 is formed only by the light emitting element 10 in FIGS. 6A and 6B, the light emitting element 10 has the second optical path (an optical path that guides light in a direction of an arrow D2) formed by the light guide 11, and the light emitting element 10 has the reflection surface 10r as the reflection surface 11r that was present in the light guide 11. The emission surface 10o of the light emitting element is fixed to the light receiving element 12 with an adhesive.

An advantage of such a configuration is that since the light guide 11 is not provided, there is no bonding process between the light guide and the light emitting element and between the light guide and the light receiving element, and thus assembly is easy, and that since one interface is reduced, a decrease in light utilization efficiency due to interface reflection can be prevented.

When an amount of the electron beam 101 emitted to the sample 7 is small and an amount of the signal electrons 102 is small, since the number of the light receiving elements 12 can be reduced and an arrangement radius can also be reduced, there may be a configuration in which only the light receiving elements 12 are provided instead of interposing the light guide in an intermediate portion. Which configuration according to Embodiment 1 and Embodiment 2 is used may be selected in consideration of a product to be applied.

The effects described in Embodiment 1, such as the effect of improving the light utilization efficiency by using the adhesive, can also be obtained in Embodiment 2.

### Embodiment 3

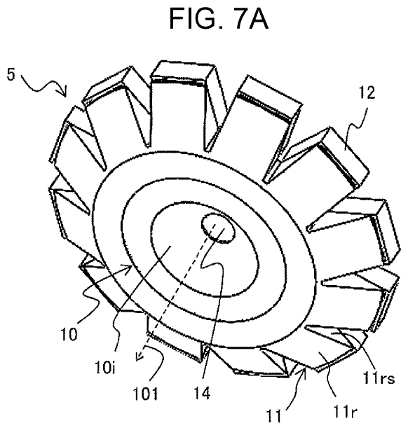

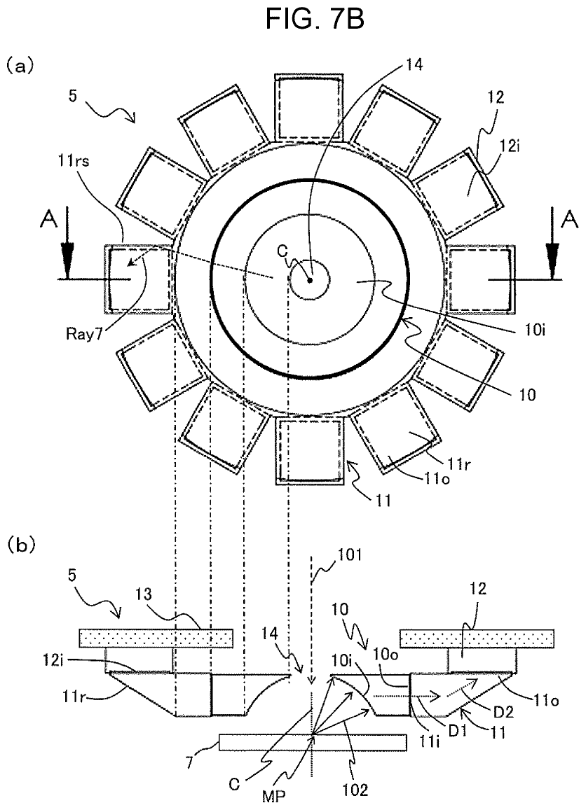

FIGS. 7A and 7B are views showing a configuration example of the detector 5 according to Embodiment 3. FIG. 7A is a perspective view. (a) of FIG. 7B is a bottom view. (b) of FIG. 7B is a cross-sectional view taken along a line A-A in (a) of FIG. 7B. Description of the same configuration as that of Embodiment 1 will be omitted.

The difference from Embodiment 1 is that the emission surface 11o and the reflection surface 11r of the light guide 11 are divided corresponding to the light receiving surfaces 12i. With such a configuration, the effect described in Embodiment 1 with reference to FIGS. 2A and 2B (the effect of preventing light from being emitted from a position different from the emission surface 11o on the surface 11rc opposite to the reflection surface 11r, and preventing the light from being lost because the light becomes stray light) can be enhanced.

A description will be given using a light ray Ray 7 in (a) of FIG. 7B. By dividing the reflection surface 11r corresponding to the light receiving surfaces 12i and using a side surface of a division portion as a reflection surface 11rs, light traveling toward a region where the light receiving element 12 is not present in the azimuth angle direction, such as the light ray Ray 7, can also be reflected by the reflection surface 11rs and returned to a region where the light receiving surface 12i is present. Accordingly, an effect of preventing a problem that light emitted from a position different from the emission surface 11o on a surface 11rc facing the reflection surface 11r becomes stray light and causes a light loss is obtained.

The effects described in Embodiment 1, such as the effect of improving the light utilization efficiency by using an adhesive, can also be obtained in Embodiment 3. As described in Embodiment 2, the light emitting element 10 may have the function of the light guide 11.

### Embodiment 4

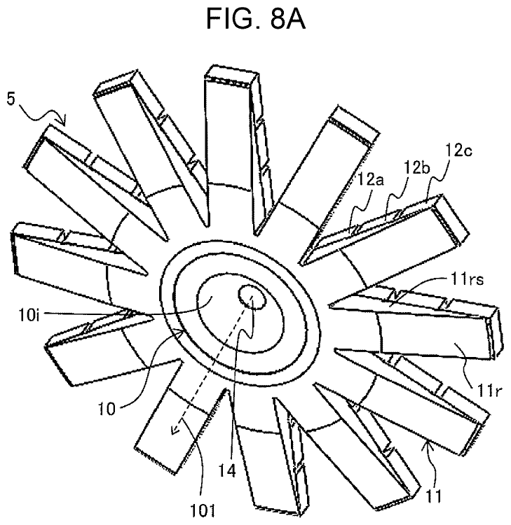

FIGS. 8A to 8C are views showing a configuration example of the detector 5 according to Embodiment 4. FIG. 8A is a perspective view. (a) of FIG. 8B is a bottom view. (b) of FIG. 8B is a cross-sectional view taken along a line A-A in (a) of FIG. 8B. FIG. 8C is a partially enlarged view of (b) of FIG. 8B.

This example is an example in which the configuration of Embodiment 3 is changed, and description of the same configuration as that of Embodiment 3 will be omitted. A difference from Embodiment 3 is that a plurality of light receiving surfaces 12i (12ia, 12ib, 12ic) of the light receiving elements are arranged along the first direction intersecting the irradiation direction of the electron beam 101. When viewed as in the bottom view of (a) of FIG. 8B, the light receiving surfaces 12i of the plurality of light receiving elements 12 (12a, 12b, 12c) are arranged along a radial direction (the first direction, a direction of an arrow D1 in (b) of FIG. 8B) from the central axis C.

In the light emitting element 10, a point where the signal electrons 102 are incident becomes a light emitting point, and several tens to several hundreds of photons are generated for one signal electron. In the configuration of Embodiment 1, these photons can be freely diffused in the azimuth angle direction, but in the configuration of Embodiment 3, the reflection surfaces 11rs are spatially limited as compared with the configuration of Embodiment 1. Therefore, in the configuration of Embodiment 3, many photons reach the light receiving element 12 close to the light emitting point more easily than that in the configuration of Embodiment 1.

Therefore, Embodiment 4 provides a configuration in which the photons emitted in a specific azimuth angle direction can be diffused and acquired.

As shown in FIGS. 8A to 8C, three light receiving surfaces 12i of the light receiving elements are arranged along the first direction, and the reflection surface 11r divided in each azimuth angle direction was provided in a manner of covering the light receiving surfaces 12i. Each of the emission surfaces 11o (11oa, 11ob, and 11oc) of the light guide faces the light receiving surface 12i, and is fixed to the facing light receiving surface with an adhesive.

With such a configuration, light is received by three light receiving elements, whereas light is received by one light receiving element 12 in each of the divided azimuths in Embodiment 3, so that the number of photons incident on one light receiving surface can be set to ⅓ by simple calculation. Therefore, the present configuration has an effect of improving the light utilization efficiency by eliminating photons that are incident between the light receiving element 12 and the light receiving element 12 and becomes a loss, and preventing saturation of the light receiving element 12 by increasing the light receiving surface 12i.

Next, the second optical path will be described. In (b) of FIG. 8B, there are a plurality of second directions (arrows D2) toward the light receiving surfaces. The second optical path is formed from a point where a surface starts to be inclined from the first direction (the arrow D1), that is, in a region radially outside a radial position where the reflection surface 11r starts in the light guide 11. The reflection surface 11r starts from a position inside an innermost light receiving surface 12ai so that the same amount of light is incident on all the light receiving elements 12.

Further, as shown in FIG. 8C, a light amount adjustment unit 11g that adjusts an amount of light incident on the light receiving element is provided before and after each light receiving element 12. The light amount adjustment unit 11g in the present embodiment includes a surface 11g1 that reflects light toward the light receiving element on a radially inner side and a surface 11g2 that reflects light toward a radially outer side.

A light ray Ray 8 in FIG. 8C is reflected by the surface 11g1 of the light amount adjustment unit 11g present between the light receiving elements 12a and 12b and is incident on the inner light receiving surface 12ia. A light ray Ray 9 is reflected by the surface 11g2 and is incident on the light receiving surface 12ic. An amount of reflection to the inner side and an amount of reflection to the outer side by the surface 11g1 and the surface 11g2 increase as the surface 11g1 and the surface 11g2 become perpendicular to the emission surface 11o.

An aluminum film or the like is preferably deposited on the surface 11g1 and the surface 11g2. When the surface 11g2 is parallel to the emission surface 11o and there is no reflective material such as aluminum, light leaks therefrom. Therefore, inclination of the surface 11g2 also prevents light leakage. Therefore, the light amount adjustment unit 11g has an effect of making an amount of light incident on the light receiving element 12 uniform in the first direction. Further, the deposition of the aluminum film on the surface 11g1 and the surface 11g2 and the inclination of the surface 11g2 relative to the emission surface also have effects of preventing leakage of light from between the light receiving elements 12 and improving the light utilization efficiency.

In the present embodiment, the light receiving elements are arranged along the first direction, and the corresponding light guides 11 are linear in a bottom view. As shown in (a) of FIG. 8B, a width W_{LGP} of the light guide when viewed from a bottom surface direction is constant from a radial position DP where the division starts in the azimuth angle direction to an outermost position in the radial direction.

When there is a portion where the width of the light guide decreases in a direction in which the light propagates, an incident angle decreases when the light is reflected by the reflection surface 11rs, a total reflection condition is not satisfied, and the light leaks from the light guide into vacuum, which causes a light loss. In order to prevent the loss caused by the light leakage, the light guide 11 has a structure in which the width does not decrease along the first direction from the radial position DP where the division starts.

Although the width W_{LGP} may vary by about 0.1 mm to 0.5 mm along the first direction for the reason of manufacturing the light guide, a fluctuation due to such variation is regarded as substantially constant. When the width W_{LGP} gradually decreases so that the inclination of the side surface (the reflection surface 11rs) in the azimuth angle direction is less than 15 degrees in the bottom view and a radial dimension of the light guide 11 is short, the light leakage is small. For example, when a length of the light guide 11 in the radial direction is about three light receiving elements as shown in (a) of FIG. 8B, the decrease in the width W_{LGP} may be regarded as small and substantially constant.

As described above, in a configuration in which the light receiving elements are arranged along the first direction, the light guide 11 is provided with the reflection surface 11rs and the light amount adjustment units 11g corresponding to the light receiving elements, and the size of the width W_{LGP} does not decrease, an effect of preventing the light leakage and improving the light utilization efficiency is obtained.

In the present embodiment, the width W_{LGP} of the light guide 11 and a width W_{RS} of the light receiving surface 12i are about the same, but the widths do not need to be about the same, and for example, the width W_{LGP} of the light guide 11 may be 1 time or less, 1.1 times or less, 1.2 times or less, 1.3 times or less, 1.4 times or less, or 1.5 times or less the width W_{RS} of the light receiving surface 12i. In the case of 1.5 times or less, the above effects can be obtained at a substantial level.

Further, the effects described in Embodiments 1 and 3, such as the effect of improving the light utilization efficiency by using the adhesive, can also be obtained in Embodiment 4. As described in Embodiment 2, the light emitting element 10 may have the function of the light guide 11.

### Embodiment 5

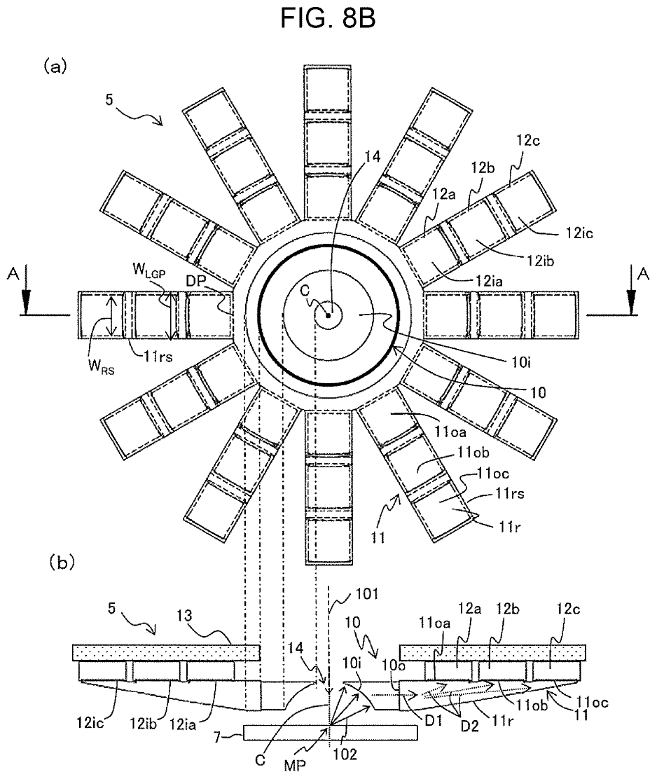

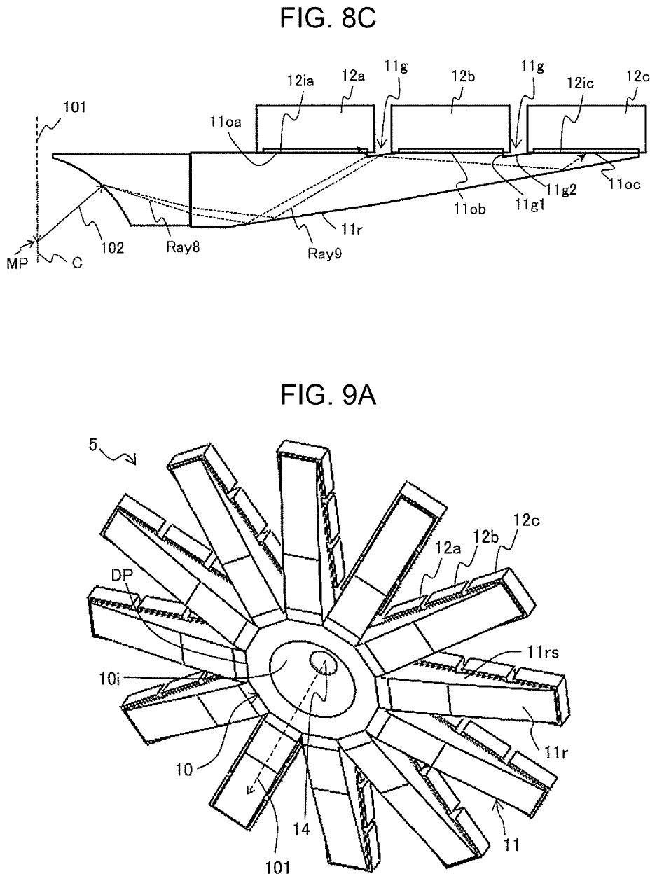

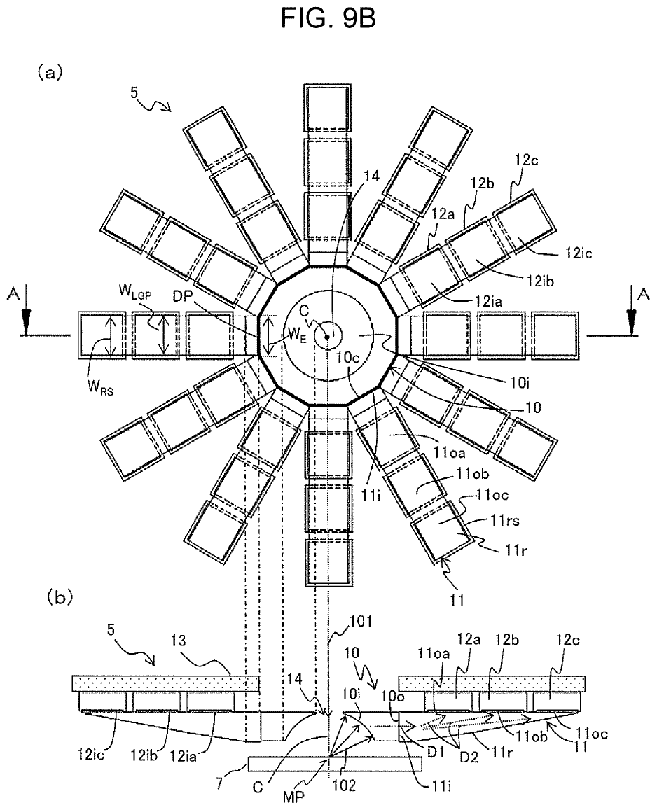

FIGS. 9A to 9C are views showing a configuration example of the detector 5 according to Embodiment 5. FIG. 9A is a perspective view. (a) of FIG. 9B is a bottom view. (b) of FIG. 9B is a cross-sectional view taken along a line A-A of (a) of FIG. 9B. FIG. 9C shows a relationship between the light guide 11 and the light emitting element 10.

This example is an example in which the configuration of Embodiment 4 is changed, and description of the same configuration as that of Embodiment 4 will be omitted. A difference from Embodiment 4 is that the light guides 11 are completely separated from one another in the azimuth angle direction (a circumferential direction) as shown in FIGS. 9A and 9B. A shape of the light guide 11 in a bottom view is an elongated shape (for example, an elongated rectangular shape) extending in the first direction, which is advantageous in that processing is simplified.

In such a configuration, the incident surface 11i of the light guide 11 in a bottom view is a straight line orthogonal to a propagation direction (the first direction) so that light incident on the light guide 11 propagates to the outermost light receiving surface 12ic. This is because, when the shape of the light guide is an elongated shape extending in the propagation direction in a bottom view and the incident surface is a surface orthogonal to the propagation direction, light continues to be guided in the light guide over a far distance in the propagation direction.

In order to face the incident surface of the light guide, the emission surface 10o of the light emitting element 10 is also a straight line in a bottom view, and an outer shape of the light emitting element 10 (indicated by a thick line in (a) of FIG. 9B) is a regular polygon equivalent to the number of divisions in the azimuth angle direction (in this example, a regular dodecagon). In the configuration in which the light guides are completely separated from one another, when the outer shape of the light emitting element 10 is a regular polygon equivalent to the number of divisions in a bottom view, light can propagate in the light guide.

Since the difference from Embodiment 4 is that the light guides are completely separated from one another in the azimuth angle direction, a cross-sectional shape taken along the line A-A shown in (b) of FIG. 9B is basically the same shape as that in (b) of FIG. 8B.

When the outer shape of the light emitting element 10 is a regular polygon in a bottom view, the width W_{LGP} of the light guide (see (a) of FIG. 9B) is preferably slightly smaller than a width W_{E} of the emission surface 10o (see FIG. 9C) of the light emitting element so that the incident surface of the light guide does not structurally interfere with each vertex. As shown in FIG. 9C, a protruding portion 10g that guides light may be provided by protruding the emission surface 10o of the light emitting element to the outside in the radial direction.

In this case, a regular polygon indicated by a dotted line in FIG. 9C can be formed by combining the widths W_{E} of the emission surfaces 10o. In other words, the width W_{E} is equal to a side of the regular polygon. That is, when the outer shape of the light emitting element 10 in a bottom view is a shape based on a regular polygon with the number of sides equal to the number of divisions, light can propagate in the light guide. Such a shape can be regarded as a shape obtained by connecting a rectangle to the outside of each side of a regular polygon. A length of a connected side of the rectangle to be connected to the regular polygon is the same as a length of one side of the regular polygon.

When the protruding portion 10g is provided, since members do not interfere with each other, the width W_{LGP} of the light guide can be made larger than the width W_{E} of the emission surface 10o of the light emitting element, and a margin can be provided so that all light emitted from the emission surface 10o can incident on a surface. Accordingly, the light utilization efficiency is improved.

The configurations described in Embodiments 1, 3, and 4, such as the improvement of the light utilization efficiency by using an adhesive, can also be applied to Embodiment 5 as appropriate, and the same effects can be obtained.

### Embodiment 6

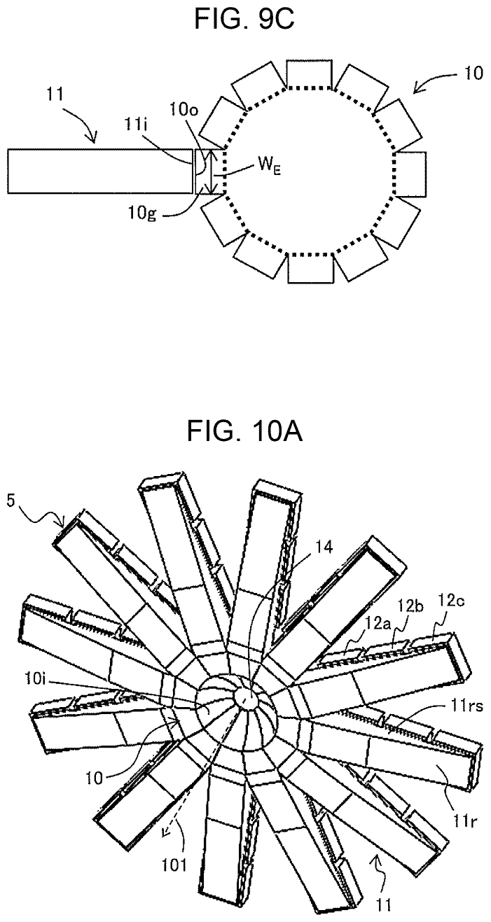

FIGS. 10A and 10B are views showing a configuration example of the detector 5 according to Embodiment 6. FIG. 10A is a perspective view. FIG. 10B is a bottom view. A cross-sectional view taken along a line A-A in FIG. 10B is the same as the cross-sectional view in (b) of FIG. 9B.

This example is an example in which the configuration of Embodiment 5 is changed, and description of the same configuration as that of Embodiment 5 will be omitted. A difference from Embodiment 5 is that, as shown in FIGS. 10A and 10B, the light emitting elements 10 are also completely separated from one another in the azimuth angle direction (the circumferential direction). That is, a plurality of light emitting elements are arranged in the circumferential direction of the electron beam.

The light emitting element 10 after division, the light guide 11, and the light receiving element 12 form an independent detection element 5e having a function of one detector. That is, when the signal electrons 102 are incident on the light receiving element 12, the emitted light reaches the light receiving element 12 through the light guide 11, and the detection element 5e has a detector function of outputting an electrical signal corresponding to the signal electrons 102. The configuration of the present embodiment is a configuration in which 12 detection elements (5e1 to 5e12) are arranged in a manner of surrounding the central axis C. Therefore, each detection element can individually measure the signal electrons 102.

In the case of such a configuration, it is possible to know in which azimuth angle direction the incoming signal electrons are detected by specifying a detection element from which a signal is obtained. That is, with such a configuration, not only saturation of a signal amount in the light emitting element 10 can be prevented, but also a signal at an azimuth angle can be discriminated. Discriminating a signal at an azimuth angle is hereinafter referred to as azimuth angle discrimination.

In particular, in the case of a semiconductor inspection device, since a semiconductor structure in recent years is three-dimensional, it is important to observe the three-dimensional structure. Human eyes recognize a solid by looking at an object from two directions. The present structure has an effect of improving visibility of a three-dimensional structure by using signals from 12 directions.

In order to achieve the azimuth angle discrimination, the light emitting elements are not necessarily arranged in an orderly manner at high density in the circumferential direction of the electron beam as in the present embodiment. In the circumferential direction, even when some of the light emitting elements are not present, it is possible to perform azimuth angle discrimination at other azimuths. That is, when a plurality of light emitting elements are arranged in the circumferential direction of the electron beam, the effect of achieving the azimuth angle discrimination is obtained.

The configurations described in Embodiments 1 to 5, such as the improvement of the light utilization efficiency by using an adhesive, can also be applied to Embodiment 5 as appropriate, and the same effect can be obtained.

### Embodiment 7

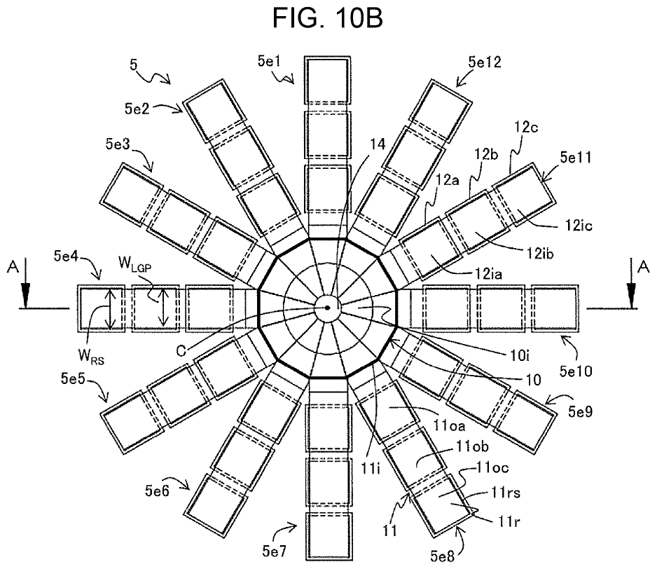

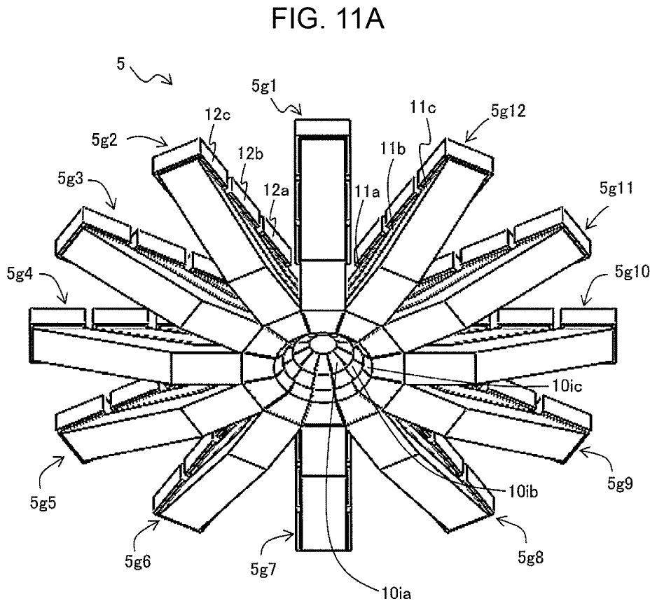

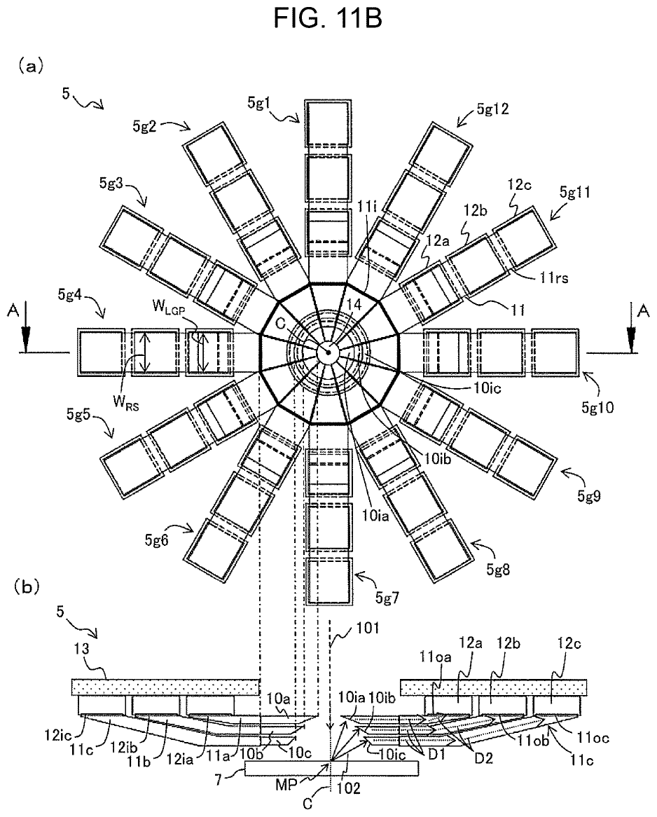

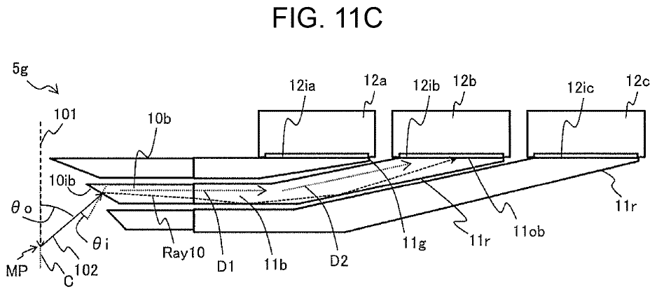

FIGS. 11A to 11C are views showing a configuration example of the detector 5 according to Embodiment 7. FIG. 11A is a perspective view. (a) of FIG. 11B is a bottom view. (b) of FIG. 11B is a cross-sectional view taken along a line A-A of (a) of FIG. 11B. FIG. 11C is a partially enlarged view of (b) of FIG. 11B.

This example is an example in which a change is applied to the configuration of Embodiment 6, and description of the same configuration as that of Embodiment 6 will be omitted. A difference from Embodiment 6 is that a plurality of light emitting elements 10 (10a, 10b, and 10c) are arranged in the irradiation direction of the electron beam 101, the light guides 11 (11a, 11b, and 11c) are provided for the respective light emitting elements 10, and each light guide 11 includes a first optical path that guides light in the first direction and a second optical path that guides light toward each of a plurality of light receiving surfaces 12i (12ia, 12ib, and 12ic) arranged along the first direction.

The light emitting element 10a, the light guide 11a, and the light receiving element 12a form an independent detection element having a function of one detector. That is, when the signal electrons 102 are incident on the light receiving element 12a, the emitted light reaches the light receiving element 12a through the light guide 11a, and an electrical signal corresponding to the signal electrons 102 is output. Similarly, the light emitting element 10b, the light guide 11b, and the light receiving element 12b form an independent detection element, and the light emitting element 10c, the light guide 11c, and the light receiving element 12c form an independent detection element.

Each detection element has characteristics of the detector described in Embodiment 1, and obtains the same effects. That is, a configuration, in which the signal electrons 102 in the minute incident surface 10i in the vicinity of the center are detected, the light emitted therefrom propagates in the first direction and is diffused, the light is received by the light receiving surface 12i having a sufficiently larger area than the incident surface 10i, forms a detector configuration in which a signal is not saturated even when a beam amount increases.

FIG. 11C shows a light ray Ray 10 as an example of a light ray propagating in a certain detection element. When the signal electrons 102 are incident on the incident surface 10ib of the light emitting element, light emitted at this incident point propagates in a direction intersecting the electron beam 101 (a direction of an arrow D1). An optical path in which the light propagates in such a direction can be regarded as a first optical path. The light guide 11b is curved in an intermediate portion, and light propagating inside the light guide 11b propagates toward the corresponding light receiving surface 12ib. A path from the curved point to the emission surface 11ob of the light guide can be regarded as a second optical path.

In the detector 5, three types of detection elements are aggregated to form one detection element group 5g (FIG. 11C shows one detection element group 5g), and the detection element groups (5g1 to 5g12) are disposed in a manner of surrounding the central axis C as shown in (a) of FIG. 11B. Each detection element group 5g has a configuration in which a space is divided by a plurality of detection elements to detect signal electrons, and an amount of light incident on each light receiving surface 12i (12ia, 12ib, 12ic) can be strictly controlled.

The light amount can be controlled by adjusting a size of the incident surface (10ia, 10ib, 10ic) of the light emitting element and adjusting an amount of the signal electrons 102 incident on the incident surface 10i. With such a configuration, by adjusting the size of the incident surface 10i such that light is uniformly incident on each light receiving surface 12i, an effect of preventing saturation of the light receiving element 12 due to an increase in a signal amount is achieved for all the light receiving elements 12 in the detector 5.

This effect is obtained in addition to the effect of preventing saturation described in Embodiments 1 to 6. Although the configuration of Embodiment 6 also has an effect of preventing saturation caused by an increase in current, the detection element group 5g in the present embodiment has a further effect of controlling the amount of light incident on each light receiving surface 12i and controlling light to be uniformly incident on the light receiving surface.

Although the arrangement is described in Embodiment 1, the arrangement of the detection elements and the detection element groups 5g with respect to the central axis C is not limited to that shown in the drawing. It is not always necessary to arrange the detection elements in a manner of completely surrounding the central axis C, and the detection elements may be disposed in a partial circumferential region (the same applies to the above-described embodiments). The effect can be obtained even with one detection element. That is, the detection element and the detection element group 5g only have an effect of preventing saturation caused by an increase in current.

Further, the plurality of light emitting elements 10 are arranged in the irradiation direction of the electron beam 101, and a signal can be individually acquired corresponding to each light emitting element, so that the signal can be discriminated in a direction of a polar angle θo. Discriminating signals in the direction of a polar angle is referred to as polar angle discrimination. Similar to the azimuth angle discrimination, the polar angle discrimination also has an effect of improving visibility of a three-dimensional structure.

Although a direction in which signal electrons are emitted varies depending on a material and a shape of the sample, even when the sample is isotropic in an azimuth angle, a difference may occur in a polar angle. Therefore, by detecting an emission polar angle of the signal electrons from the sample, more information on the material and the shape of the sample can be obtained. Since the detector of the present embodiment has the above-described configuration, the polar angle θo can be calculated based on information on the incident detection element, and the present embodiment an effect of obtaining information on the material and the shape of the sample.

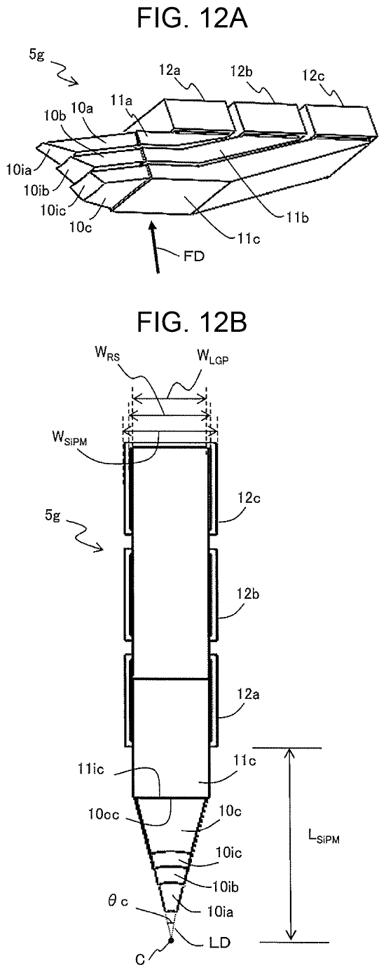

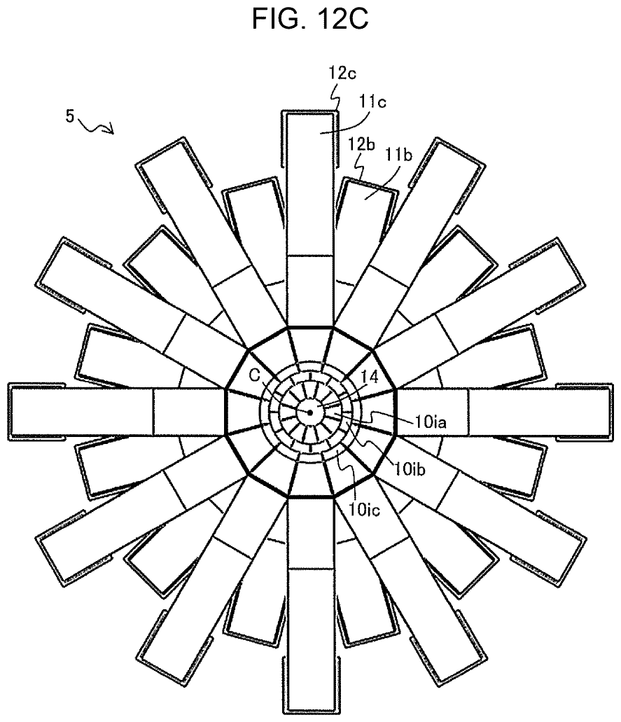

FIGS. 12A and 12B are views showing a three-dimensional structure of the detection element group 5g. FIG. 12A is a perspective view, and FIG. 12B is a bottom view as viewed from the sample 7 (from a direction of an arrow FD in FIG. 12A).

According to FIGS. 11C and 12A, the incident surface 10i (10ia, 10ib, 10ic) of the light emitting element has a shape obtained by cutting out a part of an ellipsoid such that a normal line of the surface faces the observation point MP. As described in Embodiment 1, in terms of efficiently detecting signal electrons, the incident surface 10i is most preferably a spherical surface, but since there are a plurality of the incident surfaces 10i, the incident surface 10i has a shape close to an elliptical surface which deviates from the spherical surface for the reason of manufacturing or the like. Further, the incident surface in the present embodiment is not a perfect elliptical surface, but is a flat surface (an inclined surface) having a different inclination for each incident surface when viewed in a cross-sectional view of FIG. 11C.

For the reason of improving detection efficiency of the signal electrons described in Embodiment 1, these incident surfaces are all inclined so that the incident angle θi is 30 degrees or less. When the plurality of light emitting elements 10 are arranged in the beam irradiation direction, a gap is generated between the light emitting elements in the beam irradiation direction. Therefore, in order to prevent the signal electrons 102 from entering the gaps when each incident surface is viewed from the observation point MP, the light emitting element on a side close to the sample 7 hides each gap so that the gap cannot be seen from the observation point MP.

According to FIG. 12B, when the three types of light emitting elements 10 are viewed from the bottom surface side, an intersection point of extension lines (dotted lines LD in FIG. 12B) of side surfaces of each light emitting element is substantially the same (a point on the central axis C). In other words, a central angle θc formed by two extension lines (the dotted lines LD) is the same for all the light emitting elements (10a, 10b, 10c).

This is because, as shown in (a) of FIG. 11B, the detection element group 5g has a light emitting element structure for surrounding the central axis C without a gap, and a disk-shaped light emitting element is cut into a pie shape in a bottom view. As described above, when a plurality of light emitting elements are arranged in the irradiation direction of the electron beam and the detection element group 5g is viewed from a sample side, since central angles θc of the plurality of light emitting elements are equal, there are effects that the light emitting elements 10 can be three-dimensionally arranged around the central axis C at high density, and the signal electrons 102 emitted in various directions can be detected without loss.

According to FIG. 12B, three types of light guides 11a, 11b, and 11c have the same width W_{LGP} (may be different within a range of dimensional variation), and the width W_{LGP} is substantially equal to or less than the width W_{RS} of the light receiving surface of the light receiving element. This is to increase the light utilization efficiency of the light guides.

When the emission surface 11o of the light guide is larger than the light receiving surface 12i, light is emitted to a region other than the light receiving surface, and most of the light is lost (a part of the light is scattered in the frame 12f of the light receiving element 12 and is incident on the detection surface 12d. See FIG. 5 for this structure). Therefore, an effect of preventing the loss is obtained by setting the width of the emission surface 11o of the light guide to be equal to or less than the width of the light receiving surface 12i.

When a width of an emission surface is larger than a width W_{SiPM} of the light receiving element, light emitted from the emission surface 11o protruding from the light receiving element does not reach the light receiving surface 12i, which causes a loss, and thus the width W_{LGP} of the emission surface 11o is preferably equal to or less than the width W_{SiPM} of the light receiving element (for example, 1.0 times or less, 1.1 times or less, 1.2 times or less, 1.3 times or less, 1.4 times or less, or 1.5 times or less).

Further, it is more preferable that the emission surface 11o has the same size as the light receiving surface 12i considering that the entire light receiving surface is uniformly irradiated with light. That is, both the effect of improving the light utilization efficiency and the effect of uniform irradiation can be obtained by making the emission surface 11o and the light receiving surface 12i have the same width (may be different within a range of dimensional variation). For example, when the width W_{RS} of the light receiving surface 12i is 3.0 mm, the width of the emission surface 11o may be about 2.8 mm. Such a difference in width can be regarded as being equal within a range of dimensional variation.

In addition, as shown in FIGS. 11A to 11C, 12A, and 12B, a structure in which widths of the light guides from the incident surface 11i to the emission surface 11o are set to be substantially the same without protruding has an effect of improving the light utilization efficiency. Since there is light leakage and loss when light is narrowed from a spread state in the light guide as described in Embodiment 4, when a spread shape is present in the light guide, there is light leakage and loss. Therefore, in the present embodiment, a width of the incident surface, a width of the emission surface, and a width of the light receiving surface of the light guide are configured to be substantially the same, and accordingly an effect of achieving both efficiency and uniform irradiation can be obtained.

Since the electron beam is absorbed at several tens of μm from a surface of the incident surface of the light emitting element, it may be considered that light is emitted substantially at the incident surface. In this case, it is necessary to propagate the light emitted from the incident surface through the light emitting element and further through the light guide to reach the light receiving element.

As shown in FIG. 12B, the present configuration has no portion where the width decreases from the incident surface 10i of the light emitting element to the light receiving element 12. That is, the width of the light emitting element increases from the incident surface 10ic toward the incident surface 11ic of the light guide, and the width of the light guide is constant.

As described above, the light utilization efficiency is lowered when a cross-section area in a propagation direction decreases. Therefore, the present configuration, which is an optical system in which the width from the incident surface of the light emitting element to the light receiving surface of the light receiving element does not decrease, has an effect of preventing the light utilization efficiency from being lowered.

In addition, in order to shorten the distance (the length of the optical path) of the three types of light guides 11, the light emitting elements 10 in the same azimuth angle direction (the light emitting elements belonging to the same detection element group 5g) are arranged so as to overlap one another in the beam irradiation direction, and the light guides 11 connected to the light emitting elements are also arranged in an overlapped manner. That is, the plurality of light guides 11 connected to the plurality of light emitting elements 10 have portions overlapping each other in the irradiation direction of the electron beam. With such a configuration, signal electrons can be detected at different polar angles in the same azimuth angle direction. That is, it is possible to obtain information such as how many signal electrons are emitted at which polar angle in the same azimuth angle direction. Such a configuration has an effect of achieving polar angle discrimination in the same azimuth angle direction.

In particular, by arranging the light emitting element, the light guide, and the light receiving element on the same straight line in the first direction, a distance (a length of an optical path) of the light guide 11 is shortened in each of the three types of detection elements. In a configuration in which the polar angle discrimination is achieved in the same azimuth angle direction, the light emitting element, the light guide, and the light receiving element are arranged on the same straight line, so that the distance of the light guide 11 is the shortest. When the distance (the length of the optical path) of the light guide 11 is shortened, the light utilization efficiency is improved. The present configuration has an effect of improving the light utilization efficiency.

In the same detection element group 5g, a configuration, in which a distance between the light receiving surface 12ia of the light receiving element arranged on the innermost side in the radial direction and the incident surface 10ia of the corresponding light emitting element is the shortest in the first direction, is compact in the optical system as a whole, and accordingly the light utilization efficiency is improved.

As shown in (a) of FIG. 11B, the plurality of light receiving elements 12 are arranged in a row from the central axis C in the radial direction. Further, the light emitting elements 10 and the light receiving elements 12 in the same azimuth angle direction are arranged in a row, and a shape of the light guide in a bottom view is a linear shape, so that the distance between the incident surface 11i and the emission surface 11o of the light guide is the shortest. As described above, the light utilization efficiency is maximized when the light guide has a linear shape. In addition, since the shorter the distance, the smaller a light loss, the higher the light utilization efficiency in the present configuration. Therefore, by arranging the light receiving elements 12 in a row and forming the light guide 11 into a linear shape when viewed from a sample side, there is an effect of improving the light utilization efficiency of the light guide.

When the polar angle discrimination is not achieved in the same azimuth angle direction, the light receiving elements 12 are not necessarily arranged in a row. Modifications will be described with reference to FIGS. 12C to 12E. FIG. 12C shows a bottom view of the detector 5 as viewed from a sample side, FIG. 12D shows a plan view as viewed from a side irradiated with an electron beam, and FIG. 12E shows a three-dimensional structure of the detection element group 5g. In FIG. 12D, the mounting substrate 13 is not shown. In order to avoid complexity and make it easy to see, portions that cannot be seen in the drawings are not described.

In the modifications, a detection element including the light emitting element 10b, the light guide 11b, and the light receiving element 12b rotates in the azimuth angle direction relative to a detection element including the light emitting element 10a, the light guide 11a, and the light receiving element 12a and a detection element including the light emitting element 10c, the light guide 11c, and the light receiving element 12c. A rotation angle φₕ is an angle obtained by dividing 360 degrees by twice the number of divisions, and is 360/(2×12)=15 degrees in the example of FIGS. 12C to 12E.

In the plan view of FIG. 12D, the light receiving element 12a and the light receiving element 12c are arranged in a row in the radial direction, but the light receiving element 12b is at a position rotated by the angle φₕ (15 degrees in the drawing) in the azimuth angle direction relative to the light receiving element 12a. The present configuration can be regarded as a configuration in which the light receiving elements 12 are arranged in a staggered shape (a zigzag shape) along the first direction. An advantage of such a configuration is that the light receiving elements can be arranged at high density. In the configurations of FIGS. 12C to 12E, since a distance between the central axis C and the light receiving element 12c farthest from the central axis C can be shortened as compared with a case where the light receiving elements 12 are arranged in a row as shown in FIGS. 12A and 12B, an effect of further improving the light utilization efficiency is obtained.

However, in order to perform polar angle discrimination in the same azimuth angle direction, incident surfaces of the plurality of light emitting elements (three types of 10a, 10b, and 10c in the present embodiment) for which polar angle discrimination is to be performed need to be arranged in the same azimuth angle range in a spherical coordinate system.

That is, the light emitting elements need to be arranged as shown in FIGS. 12A and 12B. As described above with reference to FIG. 12B, in the case of viewing the three types of light emitting elements 10 from a bottom surface side, it is necessary to arrange the light emitting elements such that intersection points of extension lines (dotted lines LD in FIG. 12B) of side surfaces of incident surfaces of the light emitting elements are substantially the same for the three types of light emitting elements (points on the central axis C). In other words, when viewed from the bottom surface side, the incident surfaces 10i of the light emitting elements in the same azimuth angle direction need to be substantially included in sectors having the same central angles.

In a configuration of the light emitting elements for which the polar angle discrimination in the same azimuth angle direction is to be performed, a configuration in which the light receiving elements 12 are arranged in a row, that is, a configuration shown in FIG. 12B is a configuration in which the distance (the length of the optical path) of the light guide 11 can be minimized in each of the three types of detection elements.

As can be seen from a comparison between FIG. 12A and FIG. 12E, in the modifications shown in FIGS. 12C to 12E, since the incident surfaces 10ib of the light emitting elements are shifted in the azimuth angle direction, it is not possible to perform the polar angle discrimination in the same azimuth angle direction for all of the three types of light emitting elements.

The polar angle discrimination in the same azimuth angle direction has an effect of improving visibility by increasing an amount of information on a three-dimensional structure by comparing signals for each polar angle in the same azimuth angle. Therefore, when this effect is important, a configuration in which the light receiving elements 12 are arranged in a row is preferable. However, when other effects such as light utilization efficiency and circuit area are prioritized, the light receiving elements 12 do not necessarily have to be arranged in a row. The arrangement of the light receiving elements 12 may be various arrangements including a staggered arrangement.

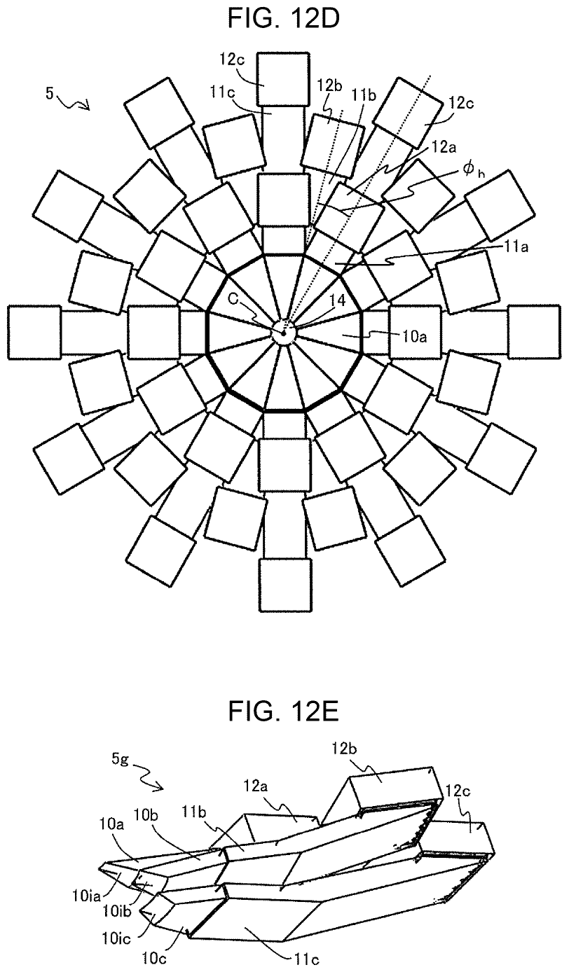

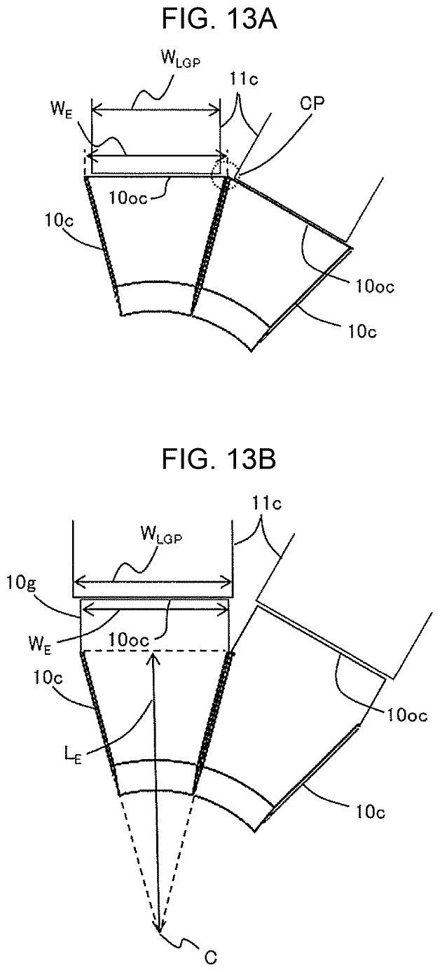

Next, structural interference of the light guides at vertexes of the light emitting elements 10 arranged in a regular polygonal shape will be described. A width W_{E} (see FIG. 9C) of the emission surface 10o of the light emitting element and a width W_{LGP} of the incident surface 11i of the light guide are substantially equal to each other in FIG. 12B, the widths will be described in detail with reference to FIGS. 13A and 13B.

FIG. 13A shows a shape example of the light emitting element 10 in Embodiment 7, and FIG. 13B shows a shape example in which the shape of the light emitting element 10 in Embodiment 7 is modified as in Embodiment 5 (FIG. 9C). The interference of the light guides at the light emitting element 10 having a non-divided regular polygonal shape has been described in Embodiment 5. A basic interference prevention method is the same.

In FIGS. 13A and 13B, the light emitting element 10c and the light guide 11c adjacent to each other in the azimuth angle direction are shown as an example. At a vertex CP where emission surfaces 10oc of the light emitting elements in FIG. 13A are adjacent to each other, the light emitting elements 10c are originally manufactured by dividing one disk, and accordingly interference does not occur, but the light guides 11 connected to the light emitting elements may interfere due to dimensional variation. Therefore, FIG. 13A shows an example in which the width W_{LGP} of the incident surface 11i of the light guide is slightly (for example, about 0.1 mm to 0.3 mm) smaller than the width W_{E} of the emission surface 10o of the light emitting element, and an effect of preventing interference is obtained.

FIG. 13B is an example in which the emission surface 10o of the light emitting element protrudes outward in the radial direction to form the protruding portion 10g for guiding light. In this case, since a gap is formed between the emission surfaces 10oc of the adjacent light emitting elements, the width W_{LGP} of the incident surface of the light guide can be made larger than the width W_{E} of the emission surface 10oc of the light emitting element, and substantially all light emitted from the light emitting element can be incident on the light guide 11c, so that the light utilization efficiency can be improved. Therefore, an effect of preventing interference of the light guides and improving the light utilization efficiency can be obtained by providing the protruding portion 10g.

For example, when a width of the light receiving surface is 3.0 mm, the width W_{LGP} of the incident surface of the light guide may be 2.8 mm, and the width W_{E} of the emission surface 10oc of the light emitting element may be about 2.7 mm.

When a distance between a radial position where the protruding portion 10g starts and the central axis C (an intersection point of extension lines of side surfaces of the light emitting elements) is denoted by L_{E}, and the number of division in the azimuth angle direction is denoted by N_{azth}, an approximate value of the width W_{E} of the emission surface 10oc of the light emitting element is generally expressed by a relationship between a side of a polygon and a side-center distance, and the value is calculated according to the following Formula 1.

$${W}_{E} = 2 \cdot {L}_{E} \cdot tan ( π / {N}_{azth} ) \qquad Formula 1$$

As described with reference to FIG. 12B, in consideration of the light utilization efficiency and uniform irradiation onto the light receiving surface of the light receiving element, the width W_{RS} of the light receiving surface of the light receiving element and the width of the emission surface of the light guide are preferably about the same. Since the light guide preferably has a linear shape, the width W_{RS} of the light receiving surface and the width of the incident surface of the light guide are also preferably the same. Since the width W_{E} of the emission surface of the light emitting element is preferably smaller than or substantially equal to (including a case of slightly larger than) the width of the incident surface of the light guide, it is preferable that the width W_{E} of the emission surface of the light emitting element is substantially equal to or smaller than the width W_{RS} of the light receiving surface.

In consideration of such matters, it is preferable that the distance L_{E} satisfies the following Formula 2 derived from Formula 1. For example, when the width of the light receiving surface is 3 mm and the light emitting element has a dodecagonal shape, the distance L_{E} is preferably smaller than 5.6 mm.

$${W}_{RS} / \{ 2 \cdot tan ( π / {N}_{azth} ) \} \geq {L}_{E} \qquad Formula 2$$

As in the present example, when the light emitting element 10 has a shape based on a regular polygon (a shape in which a rectangle is connected to an outer side of each side of the regular polygon) and the light receiving elements are arranged in a manner of surrounding the central axis C, the distance L_{SiPM} (see FIG. 12B) between the central axis C and a surface on a central axis side of the innermost light receiving element 12a and the width W_{SiPM} of the light receiving element need to satisfy the following Formula 3 (it is assumed that the length of the light guide is the same in any detection element group and the light receiving elements do not interfere with each other).

For example, when the width of the light receiving element is 3.4 mm and the light emitting element has a dodecagonal shape, the distance L_{SiPM} is preferably larger than 6.3 mm.

$${L}_{SiPM} \geq {W}_{SiPM} / \{ 2 \cdot tan ( π / {N}_{azth} ) \} \qquad Formula 3$$

A configuration satisfying Formula 3 is particularly suitable when the light receiving elements are arranged along the first direction. Although Formula 1 is derived in the configuration of FIG. 13B, in the configuration of FIG. 13A, Formula 1 is established in a similar manner by setting the distance L_{E} to a distance between the radial position of the emission surface 10oc and the central axis C (an intersection point of extension lines of the side surfaces of the light emitting elements), and Formula 2 and Formula 3 can also be applied to the configuration of FIG. 13A in a similar manner. In the present embodiment, in order to prevent structural interference, both the configuration of FIG. 13A and the configuration of FIG. 13B satisfy Formula 2 and Formula 3. The above configuration related to the distances L_{E} and L_{SiPM} has an effect of preventing interference, but the invention is not limited to such a configuration.

The configurations described in Embodiments 1 to 6 such as the improvement of the light utilization efficiency by using an adhesive can be applied to Embodiment 7 as appropriate, and the same effects can be obtained.

According to the present embodiment, an effect of enabling polar angle discrimination in a thin structure is particularly large. This point will be described below.

When the distance between the observation point MP and the light emitting element 10 is about 1 mm to 3 mm, in a configuration in the related art, which was described in Embodiment 1 with reference to FIG. 17, the azimuth angle discrimination can be performed by arranging the light receiving elements 12 in a manner of surrounding the central axis C, but it is difficult to perform the polar angle discrimination. This is because most of the signal electrons 102 (for example, signal electrons emitted within a range of a polar angle of 10 degrees to 60 degrees) are incident on the inner light emitting element 10 closest to the electron beam 101 in a concentrated manner and cannot be discriminated. In particular, in order to separate and detect signal electrons emitted within a polar angle range of 10 degrees to 50 degrees, an incident surface of the minute light emitting element is required, and thus it is difficult to perform the polar angle discrimination.

In the present embodiment, a plurality of light emitting elements are arranged in the beam irradiation direction, a light receiving element is arranged at a position farther from the electron beam than the light emitting element, and light emitted from each light emitting element is individually converted into a signal by the light receiving element. Further, light propagates in the first direction and then propagates in the second direction. Accordingly, a minute incident surface of the light emitting element can be divided, the polar angle discrimination can be performed in almost all polar angle ranges including signal electrons emitted at a small polar angle.

In other words, the light emitting elements are aggregated at the center and the light receiving elements are arranged at positions separated from one another in the first direction in the present configuration, so that a series of optical systems from the light emitting elements to the light receiving elements can be accommodated in a limited space between the objective lens 4 and the sample 7, and thus it is possible to achieve both reduction in light loss by shortening an optical path and polar angle discrimination by dividing a central portion at high density. At a position where a large number of signal electrons can be detected, the effect of obtaining the polar angle discrimination function is enhanced by the present configuration.

There are various methods for arranging the light emitting elements in the beam irradiation direction. As shown in FIG. 12A, there is an arrangement in which the incident surfaces of the light emitting elements are arranged substantially in a row along the beam irradiation direction, and as shown in FIGS. 12C to 12E, there is an arrangement in which the incident surfaces of the light emitting elements are arranged in a zigzag shape along the beam irradiation direction.

In FIG. 12A and FIG. 12E, a difference in the arrangement of the light emitting elements in the beam irradiation direction is caused by making the arrangement of the light receiving elements in the first direction different under a condition that the light guide has a linear shape in the bottom view. That is, since the arrangement of the light emitting elements in the beam irradiation direction changes due to an influence of a shape of the light guide and the arrangement of the light receiving elements, the arrangement is not limited to those as shown in FIGS. 12A and 12E, and there are various arrangements such as changing the number of divisions of the light emitting elements and a positional relationship according to positions in the beam irradiation direction.

When a plurality of light emitting elements are arranged in the beam irradiation direction, the effects of achieving the polar angle discrimination described above, preventing signal saturation due to an increase in a beam amount, and the like are obtained, and thus it is sufficient that the plurality of light emitting elements are arranged in the beam irradiation direction.

From the viewpoint of preventing signal saturation due to an increase in the beam amount, the arrangement of the light receiving elements 12 in the first direction is not necessarily a straight line. For example, in a bottom view, the light receiving elements 12 may be arranged so as to meander in the first direction (in a staggered shape, a zigzag shape) in order to prevent interference in the arrangement of the light receiving elements 12. In such a case, for example, the light guide 11 that is curved in a bottom view may be used.

When the light receiving elements 12 are arranged at a high density, the number of light receiving elements may vary between a circumference close to the central axis C and a circumference far from the central axis C. In this case, the number of divisions in the azimuth angle direction may be different in each detection element included in the same detection element group 5g, or there may be a light guide that branches from one incident surface to a large number of emission surfaces, such as a light guide having a bifurcated shape.

Further, various modifications can be made without departing from the gist of acquiring the signal electrons 102 on the minute incident surface 10i of the light emitting element near the central axis C and propagating and diffusing the light in the first direction.

### Embodiment 8

FIGS. 14A to 14D are views showing configuration examples of the detector 5 according to Embodiment 8. FIG. 14A is a perspective view. (a) of FIG. 14B is a bottom view. (b) of FIG. 14B is a cross-sectional view taken along a line A-A in (a) of FIG. 14B. FIG. 14C is a partially enlarged view of (b) of FIG. 14B. FIG. 14D is a perspective view showing the detection element group 5g.

This example is an example in which the configuration of Embodiment 7 is changed, and description of the same configuration as that of Embodiment 7 will be omitted. A difference from Embodiment 7 is that a planar element is used as the light emitting element 10 (10a, 10b, 10c).

A crystal light emitting element can be processed into various shapes, and there is a planar light emitting element such as a thin plate and a thin film, and it is preferable to use these light emitting elements as appropriate. For example, a thin film obtained by film-forming a powder phosphor has a feature of high light extraction efficiency from the powder, and there is a material having a high emission intensity.

Such a material is, for example, YSO (Y₂SiO₅: Ce). The material is not limited thereto, powder of YAP, YAG, GGAG, GOS, or the like described in Embodiment 1 can also be used as a crystalline light emitting element material. The crystal light emitting element described in Embodiment 1 may also be used as a planar element because it is easy to process the crystal light emitting element, and in this case, a configuration of the present embodiment may be applied.

In addition, ZnO or GaN, which is a semiconductor material, is used as a material having a rapid response speed from light emission to extinction. These materials are often used as planar thin plates. In particular, in the case of a light emitting element having a quantum well structure therein, the quantum well structure is formed on a flat substrate, and therefore is usually used as a thin plate. A representative example of a light emitting element having a quantum well structure is a GaN scintillator, and a quantum well structure in which InGaN and GaN are stacked is used as a light emitting unit. It is needless to say that the invention is not limited by a material of the light emitting element.

The present embodiment provides a configuration suitable for a planar element. FIGS. 14A to 14D show a case where a flat plate of a GaN scintillator is used as the light emitting element 10. As shown in (b) of FIG. 14B, FIG. 14C, and FIG. 14D, the light guide 11 extends to the vicinity of the center as compared with Embodiment 7, and the emission surface 10o of the light emitting element is bonded to the incident surface 11i of the light guide 11.

Further, the incident surface 11i of the light guide is inclined relative to the irradiation direction of the electron beam 101 so that the normal line of the surface of the incident surface 10i of the light emitting element faces the observation point MP. The incident surface 11i of the light guide is inclined so that the incident angle θi of the signal electrons 102 onto the incident surface 10i of the light emitting element is 30 degrees or less.

The inclined incident surface 11i also has an effect of reflecting light in the first direction (an arrow D1). This effect will be described below. As indicated by a light ray Ray 11 in FIG. 14C, there is a light ray incident on the light guide 11b is incident again on the light emitting element 10b, is reflected by the incident surface 10ib of the light emitting element, is incident again on the light guide 11b, and propagates toward the light receiving element 12. Although an example in which the light is incident again on the light emitting element 10b and is reflected by the incident surface 10ib has been described, the light may be not incident again on the light emitting element 10b and may be Fresnel reflected by an interface between the light guide 11b and the light emitting element 10b to follow the same path. Since there is such a path, the inclined incident surface 11i also has an effect of reflecting light in the first direction (the arrow D1).

In the case of a planar light emitting element, since light emission in a normal line direction of the plane increases, a path such as a path of the light ray Ray 11 is likely to occur, and the effect of the inclined incident surface 11i is enhanced.

As shown in FIGS. 14A and 14D, the incident surfaces 10i of the light emitting elements are disposed to three-dimensionally cover the observation point MP, that is, are disposed to have a range not only in the radial direction of the electron beam 101 but also in the irradiation direction. In order to combine planes and three-dimensionally cover the observation point MP, a planar shape of the incident surface 10i of the light emitting element is a trapezoid having a long side on the sample 7 side. Although other shapes such as a hexagon can be considered, a trapezoid is preferable to surround the observation point MP without a gap, and the shape is simple to process, which is practical.

FIG. 14E and FIG. 14F show structure examples in the case of using powder light emitting elements. As shown in FIG. 14E, a powder film 10p may be formed on a substrate 10s made of glass or the like, and the substrate 10s on which the powder film 10p is formed may be used as the light emitting element 10. As shown in FIG. 14F, the powder film 10p may be directly formed on the incident surface 11i of the light guide 11 to form the light emitting element 10.

In either case, the incident surface 10i of the light emitting element is a surface on a vacuum side of the powder film (a surface on an air side, or a surface not in contact with the substrate or the light guide). When the substrate 10s is used (FIG. 14E), the emission surface 10o is a surface of the substrate 10s facing the incident surface 11i of the light guide (a surface attached to the light guide 11), and when a film is formed on the light guide 11 (FIG. 14F), the emission surface 10o is a surface of the powder film facing the incident surface 11i of the light guide.

It is preferable that the incident surface 10i is covered with a protective film or an aluminum film for preventing electrification without exposing the powder (not shown). The powder film is formed by adhering the powder phosphor 10ph. Therefore, a thickness variation occurs. An average thickness is about several μm to several tens of μm.

In the present embodiment, the incident surface 10i of the light emitting element is inclined relative to the irradiation direction of the electron beam 101, that is, inclined relative to the first direction (the arrow D1). However, when only the effect of light reflection in the first direction is considered, as described in the Embodiment 1, the same effect can be obtained by, for example, making the incident surface 10i parallel to the first direction or inclining the surface opposite to the incident surface 10i in the beam irradiation direction relative to the first direction as a modification.

FIG. 14G shows a cross-sectional view in the vicinity of the incident surface 10i in such a modification. The incident surface 10i is parallel to the first direction (an arrow D1), and of the light guide 11, a surface 11ir opposite to the incident surface 10i in the beam irradiation direction is inclined relative to the first direction. In this case, light is reflected by the surface 11ir and propagates in the first direction. Both the incident surface 10i and the surface 11ir opposite to the incident surface 10i may be inclined relative to the first direction.

As shown in FIG. 14C, light emitted by the light emitting element 10 is incident on the light guide 11 and propagates in the first direction (a direction of the arrow D1). In an optical system including a light emitting element and a light guide, a region where light propagates in the first direction forms a first optical path. An optical path that guides light in a direction from the first optical path to the light receiving surface (a direction of an arrow D2) is a second optical path.

In the configurations described in Embodiments 1 and 3 to 7, by adopting the configuration shown in the present embodiment in the vicinity of the light emitting element 10 and the incident surface 11i of the light guide, various effects described in Embodiments 1 and 3 to 7 can be obtained even when the light emitting element is planar. In other words, a configuration in which the planar light emitting element is provided at a tip end of the light guide can be appropriately applied to the configurations described in Embodiments 1 and 3 to 7 regardless of a division method of the light guide or the like, and the same effects can be obtained.

### Embodiment 9

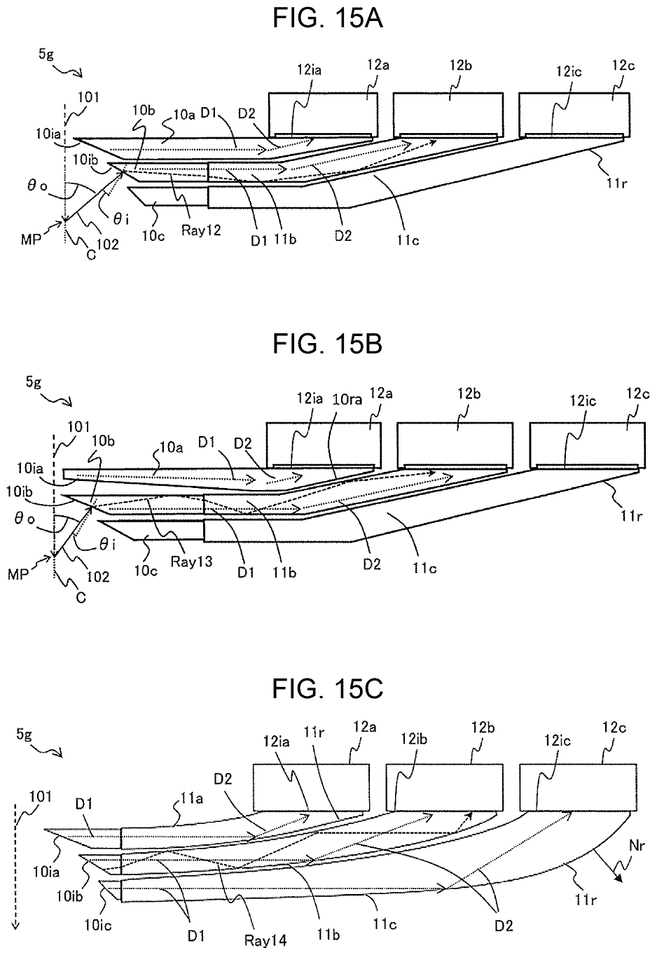

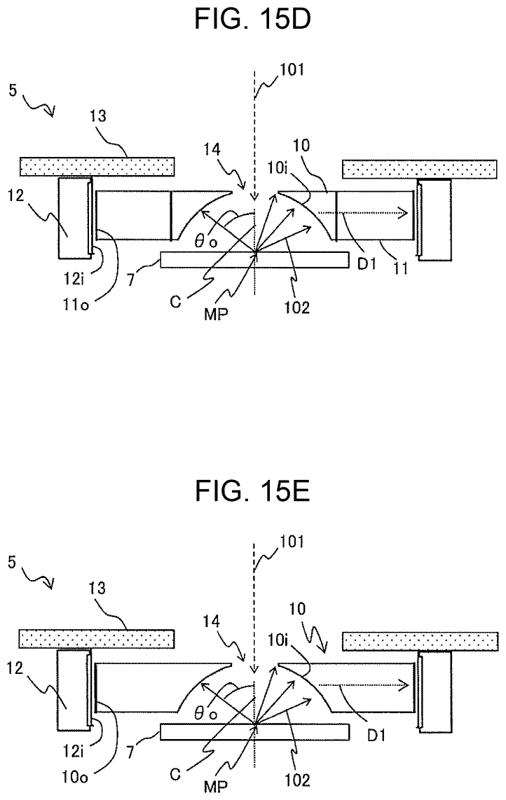

Various features described in Embodiments 1 to 8 may be used in combination as appropriate. Combination examples and modification examples of members will be described with reference to FIGS. 15A to 15C.

FIG. 15A is a view showing the detection element group 5g including a detection element (including the light emitting element 10b, the light guide 11b, and the light receiving element 12b) having the light guide 11, another detection element (including the light emitting element 10c, the light guide 11c, and the light receiving element 12c) having the light guide 11, and another detection element (including the light emitting element 10a and the light receiving element 12a) having no light guide 11.

The detection element having no light guide 11 is a detection element having the shortest optical path, and a portion through which light propagates has a planar shape that can be processed and manufactured from a flat plate or a disk. Since it is possible to cut a plate material of the light emitting element 10 obliquely or the like, the present embodiment is an example in which a flat plate or disk light emitting element is processed to provide a function of the light guide in the light emitting element.

The light emitting element 10a forms an optical path for guiding light in the first direction (a direction of an arrow D1) and an optical path for guiding light in the second direction (a direction of an arrow D2). The light emitting element has the same function as the light emitting element 10 shown in (b) of FIG. 6B, and has the advantages described in Embodiment 2.

In the two detection elements having the light guide 11, since the second optical path is curved to have a three-dimensional shape, it is difficult to process the light emitting element into such a shape, or a processing time is long, which is not practical. Therefore, in the case of a shape that cannot be easily processed from a plate material, it is preferable to use a light guide. The present configuration is an example in which a configuration in which a light guide is used and a configuration in which no light guide is used are appropriately combined in accordance with a propagation path of light.

FIG. 15B is a configuration example for creating a first image whose main signal source is X-rays using one of the detection elements and creating a second image whose main signal source is electrons using another detection element. Specifically, in this example, a light emitting element (for example, the light emitting element 10a) of a certain detection element is made of a radiation material having high transmittance of X-rays or the like, and a light emitting element (for example, the light emitting elements 10b and 10c) of another detection element is made of a material for electron beams.

When the sample 7 is irradiated with the electron beam 101, X-rays are generated together with the signal electrons 102. The present configuration is a configuration for detecting the signal electrons 102 and the X-rays as signals. In order to efficiently detect the X-rays, it is preferable to use a light emitting element that efficiently emits the X-rays. That is, in order to discriminate and individually detect the X-rays and the signal electrons, light emitting elements made of different materials may be used for X-rays and electron beams. When a material containing GGAG (Gd₃(AlGa)₅O₁₂), YAG (Y₃Al₅O₁₂), LuAG(Lu₃Al₅O₁₂), GOS(Gd₂O₂S), YOS(Y₂O₂S), GSO(Gd₂SiO₅), LSO(Lu₂SiO₅), YSO(Y₂SiO₅), CWO(CdWO₄), BGO(Bi₄Ge₃O₁₂), CsI, NaI, YAP, or the like as a base material is used as a material of the light emitting element for X-rays, good characteristics can be obtained. Some materials are used for both X-rays and electrons. In addition, materials other than those described above may be used.

Since the electron beam has smaller transmission power than the X-rays, it is preferable to detect the electron beam using two of the light emitting elements 10b and 10c close to the sample 7. Radiation having high transmittance such as X-rays is transmitted through the light emitting elements 10b and 10c and the light guides 11b and 11c without being absorbed, and reaches the light emitting element 10a of a detection element for X-rays, so that the X-rays can be detected. The detection element for X-rays can efficiently detect only X-rays without detecting the electron beam by making the light emitting material different between a side close to the sample and a side far from the sample and arranging the light emitting element for detecting X-rays on the side far from the sample.

With such a configuration, X-rays and electron beams can be discriminated and detected. That is, it is possible to form an SEM image of only X-rays by a certain detection element and an SEM image of mainly electron beams by another detection element.

Although the material of the light emitting element is different between the X-rays and the electron beam, the invention is not limited thereto, and the same material may be used since YAP, YAG, or the like can be used for both the electron beam and the X-rays.

In addition, the detection element for X-rays does not include a light guide. The reason is to increase a length of the light emitting element 10a to increase an area of the incident surface and increase a signal amount because the radiation transmits various substances including the sample 7 and is emitted to a wide range. The light emitting element 10a has an optical path that propagates light toward the light receiving element 12a (in a direction of the arrow D1) positioned at a position separated from the light emitting element 10a in the first direction and then propagates light toward the light receiving surface 12ia (in a direction of the arrow D2) by a reflection surface 10ra. The detection element for X-rays may also include a light guide.

In addition, although the light emitting element for efficiently detecting the X-rays is disposed on a side farthest from the sample, since the signal electrons 102 are detected on the incident surface 10i at a tip end of the light emitting element, other arrangements are also possible. For example, by changing a length in the radial direction, the light emitting element 10b present at an intermediate position can be used for X-rays, and the light emitting element 10c closest to the sample can be used for X-rays. Which position is used for X-rays may be set to an optimum position as appropriate in consideration of a shape of the incident surface.

Such a configuration for detecting X-rays and an electron beam at the same time is implemented by arranging a plurality of light emitting elements in the beam irradiation direction, separately providing a light emitting element for detecting the X-rays and a light emitting element for detecting the electron beam, arranging light receiving elements in the first direction, and including an optical system for individually propagating light from each light emitting element to each light receiving element. That is, the configuration of the detection element group described in Embodiment 9 enables simultaneous detection of different quanta (in this case, the X-rays and the electron beam), and the configuration of Embodiment 2 is more preferable used for only a detection element for X-rays.

Further, it is preferable to use a plurality of types of light emitting elements, and an effect of improving detection efficiency is obtained by using both a light emitting element for X-rays or and a light emitting element for an electron beam. In addition, it is preferable that a detection element farthest from the sample is used for X-rays, and accordingly effects of reducing a probability that the electron beam is incident on the light emitting element for X-rays, and generating only an image for X-rays can be obtained.

FIG. 15C shows a configuration example in which a cross-sectional shape of the light guide 11 is curved. In this case, cross-sectional shapes of the light emitting element 10 and the light guide 11 may not have planes completely parallel to the first direction (an arrow D1). However, since the light receiving surface 12i of the light receiving element is positioned at a position separated from the incident surface 10i of the light emitting element in the first direction and the light receiving surface 12i is positioned on a side where the electron beam 101 flies to the light emitting element 10, an optical path connecting the incident surface 10i and the light receiving surface 12i includes an optical path in which light travels in the first direction and an optical path in which light travels in the second direction.

When the cross-sectional shape is curved, it is difficult to strictly separate the first optical path and the second optical path, but for example, the following definition is possible. In the light guide 11, the first optical path that guides light in the first direction is formed in the vicinity of a radially inner end portion of the electron beam 101. On the other hand, in the light guide 11, the second optical path that guides light in the second direction is formed in the vicinity of a radially outer end portion of the electron beam 101. The other portion (a portion between the first optical path and the second optical path) can be regarded as an optical path connecting the first optical path and the second optical path.

In this manner, it can be said that the light guide 11 forms at least a part of the second optical path. In the example of FIG. 15C, the light guide 11 also forms the first optical path, but the first optical path may be formed by the light emitting element. Further, a part of the second optical path (particularly, a region on the first optical path side) can be formed by the light emitting element, and the entire optical path including the first optical path and the second optical path can be formed by the light emitting element (that is, the light guide is not used).

Other definitions are also possible. As shown in FIG. 15C, the first optical path may extend from the incident surface 10i in the first direction (the arrow D1) to an intersection point with the light emitting element 10 or the light guide 11, and the second optical path may extend from the intersection point to the light receiving surface 12i. Basically, this definition is established when the cross-sectional shape is a straight line.

In FIG. 15C, the second direction (arrow D2) is represented by a straight line, but in a case where the cross-sectional shape is a more complicated curve shape, the second direction may intersect the cross section and cannot be clearly defined. In this case, the optical path from the intersection point to the light receiving surface 12i can also be set as the second optical path in a similar manner.

In addition, the definition may be made according to a method described in Embodiment 1 and the like or characteristics of an optical path. When concepts and characteristics are the same, an appropriate definition method may be used according to a shape. For example, the second optical path may be at a position where an amount of light propagating in a direction different from the first direction starts to increase.

In particular, when a thickness of the detector is about the same as or slightly larger than a size of the light receiving element 12 (in the present embodiment, the size of the light receiving element is 3.4 mm and the thickness of the detector is 3 mm to 7 mm), a propagation distance of light in the first direction is longer than a propagation distance in a direction orthogonal to the first direction. This is because the light cannot be diffused in a thickness direction because the detector is thin, and thus the light propagates in the first direction to diffuse the light.

Each of the light guides (11a, 11b, and 11c) in FIG. 15C has an optical path for propagating light in the first direction (the arrow D1) and an optical path for propagating light in the second direction (the arrow D2). Whether the cross-sectional shape is a curved surface or a straight line may be appropriately selected according to a positional relationship between a position of the incident surface 10i of the light emitting element and the light receiving surface 12i of the light receiving element. In any case, the light emitting elements are concentrated at the center, the light receiving elements are arranged at positions separated from the light emitting elements in the first direction, and an optical system including the light guides and the light emitting elements has the first optical path and the second optical path.

A shape of each of the light guides has the reflection surface 11r facing the light receiving surface 12i, and the reflection surface 11r reflects, in the second direction, a part of the light traveling in the first direction. A normal line of the reflection surface 11r will be described. The reflection surface 11r is a surface whose normal line is not orthogonal to the first direction. Among normal line vectors of the reflection surface, when a direction toward an outer side of the light guide is defined as a normal line Nr, the normal line Nr is inclined radially outward.

### [Modification of Embodiment 1]

FIG. 15D shows a modification of Embodiment 1. Although the light receiving surface 12i and the first direction (the arrow D1) are substantially parallel to each other in FIGS. 2A and 2B of Embodiment 1, the light receiving surface 12i and the first direction may be inclined relative to each other as described above. As an example of being inclined to an utmost limit, the light receiving elements may be arranged in a vertical direction such that the first direction (the arrow D1) and the light receiving surface 12i are substantially orthogonal to each other. When the first direction and the light receiving surface 12i are substantially orthogonal to each other, the concept of detecting the signal electrons 102 at the center and propagating and diffusing light in the first direction is the same, and the same effects as those described in Embodiment 1 and the like is obtained. However, since the second direction coincides with the first direction, the configuration is different from that in Embodiment 1.

A large difference between the configuration of FIG. 15D and the configurations of FIGS. 2A and 2B is that the light receiving surface 12i of the light receiving element 12 faces a center direction, and light propagates in the first direction and reaches the light receiving surface 12i. In other words, it can be said that the normal line of the light receiving surface 12i is substantially parallel to the first direction, and the electron beam 101 is directed in a certain direction (radially inward).

In this modification, the detector 5 has a transparent region (a region formed by the light emitting element 10 and the light guide 11) that propagates light from the incident surface 10i of the light emitting element 10 on which the signal electrons 102 are incident to the light receiving surface 12i of the light receiving element 12 in a similar manner to the embodiments described above.

In FIG. 15D, the light receiving element 12 has an electrode on a side surface and is mounted on the mounting substrate 13 by soldering or the like. As another mounting method, the light receiving element 12 is mounted on the mounting substrate 13 via an L-shaped metal fitting or the like in order to stand vertically with respect to the mounting substrate 13. When an L-shaped metal fitting or the like is used, electrical connection may be performed using a lead wire. In such a configuration, since the light propagating in the first direction reaches the light receiving surface 12i without changing a direction, the light utilization efficiency is improved. Further, since there is no light receiving element between the mounting substrate 13 and the first optical path, the detector can be made thinner (an axial dimension can be reduced) accordingly.

Although the normal line of the light receiving surface 12i is parallel to the first direction in the example of FIG. 15D, the normal line may not be strictly parallel to the first direction. For example, the normal line of the light receiving surface 12i may form an angle of 10 degrees or less, 20 degrees or less, 30 degrees or less, or 45 degrees or less with the first direction, and the light utilization efficiency can be increased according to the angle. Although related to a shape of the incident surface 10i or the like, in many cases, the light utilization efficiency is maximized when the normal line of the light receiving surface 12i is parallel to the first direction.

### [Modification of Embodiment 2]

FIG. 15E shows a modification of Embodiment 2. The present configuration can also be considered as an example obtained by further modifying the modification shown in FIG. 15D. Although the light receiving surface 12i and the first direction (the arrow D1) are substantially parallel to each other in Embodiment 2 (FIGS. 6A and 6B), the light receiving surface 12i and the first direction may be inclined as described above. As an example of being inclined to the utmost limit, the light receiving elements may be arranged in a vertical direction such that the first direction and the light receiving surface 12i are substantially orthogonal to each other.

FIG. 15E shows an example in which there is no light guide in the configuration described in FIG. 15D. The advantage of making the light receiving surface 12i orthogonal to the first direction is as described with reference to FIG. 15D. As described in Embodiment 2 (FIGS. 6A and 6B), the effect of eliminating the light guide 11 is that since the light guide 11 is not provided, there is no bonding step between the light guide and the light emitting element or between the light guide and the light receiving element, so that the assembly is easy, and that since the number of interfaces is reduced by one, a decrease in light utilization efficiency due to interface reflection can be prevented.

Although the normal line of the light receiving surface 12i is parallel to the first direction in the example of FIG. 15E, the normal line may not be strictly parallel to the first direction. For example, the normal line of the light receiving surface 12i may form an angle of 10 degrees or less, 20 degrees or less, 30 degrees or less, or 45 degrees or less with the first direction, and the light utilization efficiency can be increased according to the angle. Although related to a shape of the incident surface 10i or the like, in many cases, the light utilization efficiency is maximized when the normal line of the light receiving surface 12i is parallel to the first direction.

### Embodiment 10

Embodiments 1 to 9 describes detectors capable of efficiently detecting quanta such as signal electrons or radiation emitted from an observation point and outputting an electrical signal without saturation even when an amount of the quanta such as signal electrons or radiation incident on the detector increases. Since more functions can be implemented by using the detectors, the functions will be described in Embodiment 10.

Embodiment 10 provides a measurement device including the detector in Embodiment 7. In Embodiment 6, the detection element 5e is provided for each azimuth angle to enable azimuth angle discrimination. Further, in Embodiment 7, the plurality of light emitting elements 10 are arranged in the beam irradiation direction, and a detection element is provided for each polar angle, so that polar angle discrimination can be achieved in addition to azimuth angle discrimination. That is, in Embodiment 10, the plurality of light emitting elements 10 are arranged in the beam irradiation direction, and when the azimuth angle is defined with the beam irradiation direction as the central axis, the plurality of light emitting elements 10 are also arranged in the azimuth angle direction.

In Embodiment 6, signals of the signal electrons 102 can be output individually from 12 detection elements, and in Embodiments 7 and 8, signals of the signal electrons 102 can be output individually from 36 detection elements. In this case, with respect to all signal electrons 102 incident on the detector, the number of signal electrons 102 incident on each detection element is 1/12 and 1/36, respectively. For example, in a case where the number of signal electrons is 1/36, when an amount of the electron beam 101 is not increased and is used at about 1 nA or less, an interval between the signal electrons 102 incident on each detection element is about several tens to several hundreds of ns.

On the other hand, a response time from when the signal electrons 102 are incident on the light emitting element 10 to emit light up to when light emission ends is about several tens to several hundred ns. This response time is a response time of a detector required to detect one signal electron 102. By using the elements that can perform individual detection as in Embodiments 6 to 8, an interval of the signal electrons 102 incident on each detection element can be extended to be longer than the response time, and the signal electrons 102 can be detected as discrete pulse signals. That is, the number of signal electrons 102 can be counted as the number of pulse signals according to an irradiation position of the electron beam 101, an SEM image can be created by pulse counting (the number of signal electrons), and visibility can be improved by a new observation image.

Further, in the case of a detector in which the light utilization efficiency is sufficiently increased by using a technique for improving the light utilization efficiency described in the present specification, since a pulse height and energy of the signal electrons 102 are approximately proportional to each other, the energy of the signal electron 102 can be measured based on the pulse height, and a signal can be discriminated according to the energy of the signal electron 102. Discriminating a signal according to energy is referred to as energy discrimination. Alternatively, pulse height discrimination may be performed by discriminating a signal according to the pulse height of a pulse signal.

By using a detector capable of performing individual detection and having high light utilization efficiency as shown in Embodiments 6 to 8, not only pulse counting but also energy discrimination can be performed. By performing the energy discrimination, image contrast can be improved and information in a depth direction of an observation target can be obtained, so that visibility can be further improved.

When the light utilization efficiency is low, a probability that emitted photons reach the light receiving element 12 is low, and thus a variation in the number of photons reaching the light receiving element 12 is large. Since the number of photons of signal electrons having close energy does not change much, a difference in the number of photons cannot be discriminated when the light utilization efficiency is low. That is, when the light utilization efficiency is low, energy resolution deteriorates and energy discrimination cannot be performed.

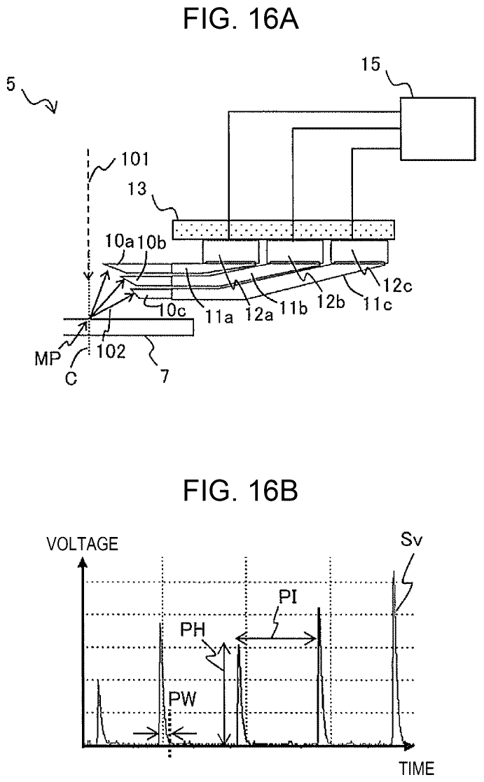

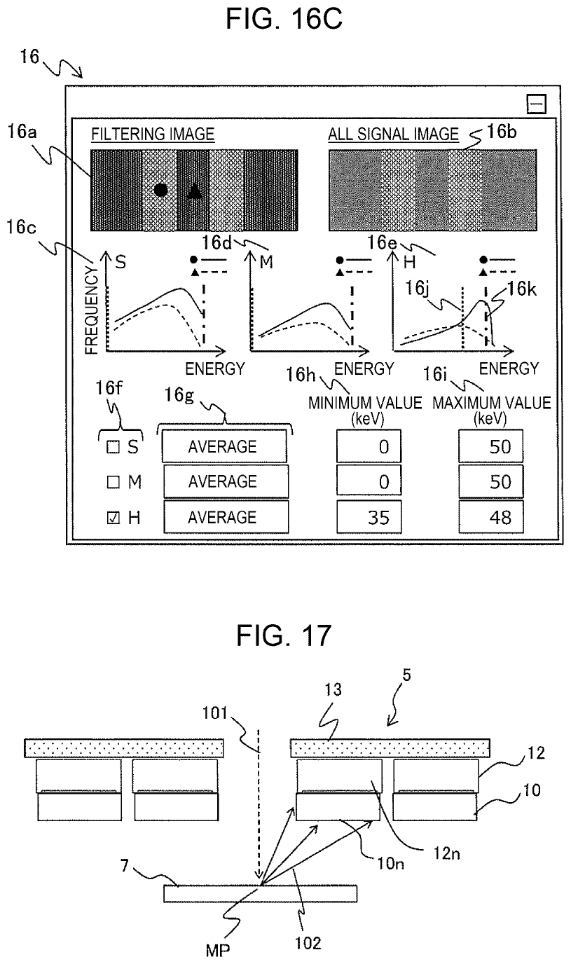

A configuration example of a measurement device according to Embodiment 10 will be described with reference to FIGS. 16A to 16C. FIG. 16A shows a part of a detector. Each light receiving element 12 is wired to individually transmit an electrical signal to a detection circuit 15. In general, a current signal is output from the light receiving element 12. The current signal is converted into an easy-to-handle voltage signal and amplified by the detection circuit 15. Further, the detection circuit 15 in the present embodiment digitizes the obtained voltage signal by analog-to-digital conversion, and stores the digitized voltage signal in a storage device (not shown) provided in the system control unit 8 or the like.

FIG. 16B is a diagram showing a voltage signal Sv generated by the detection circuit 15. A vertical axis represents a voltage, and a horizontal axis represents time. FIG. 16B shows an example in which the amount of the electron beam 101 is sufficiently small, and shows five pulse signals corresponding to five signal electrons 102.

A pulse width PW indicates an approximate response time of a detection element, and a pulse height PH indicates an amount proportional to the energy of the signal electron 102. Therefore, the energy of the signal electron 102 can be measured by measuring the pulse height PH. However, strictly speaking, when a histogram of the pulse height PH is created and the vicinity of a peak of the histogram is fitted with a Gaussian distribution excluding noises on a low pulse side, an average of pulse height values is proportional to the energy of the signal electron.

As shown in FIG. 16B, when a pulse interval PI is longer than the response time of the detection element, that is, the pulse width PW, the pulse height PH can be accurately measured. When a plurality of signal electrons 102 are incident within the response time of the detection element, a plurality of pulse signals overlap with one another. When the number of incident signal electrons within the response time becomes sufficiently large, the voltage signal Sv becomes a continuous curve, and pulses cannot be discriminated from one another.

As described in Embodiments 6 to 8, with a configuration in which a plurality of detection elements are arranged and electrical signals can be individually output from the detection elements, it is possible to reduce the number of signal electrons incident per detection element and extend a pulse interval PI in each detection element. This makes it possible to measure the pulse height PH by reducing overlapping of pulses, and measure the energy of the signal electron 102. That is, with the configurations described in Embodiments 6 to 8, not only the saturation of a signal amount in the light emitting element 10 can be prevented, but also the energy discrimination of the signal electrons 102 can be performed.

In an electron microscope, signal electrons scattered at a deep position of the sample 7 lose more energy than the signal electrons before the signal electrons are incident on the sample 7. Therefore, the energy of the signal electrons includes information on a structure of the sample 7 in a depth direction. As described above, particularly in the case of a semiconductor inspection device, since a semiconductor structure in recent years is three-dimensional, it is important to observe the three-dimensional structure. Therefore, in order to obtain the information in the depth direction, it is important to utilize energy information of the signal electrons 102. Further, since an energy spectrum of the signal electrons 102 varies depending on a composition distribution of the sample, the energy of the signal electrons includes information on compositions of the sample 7, and the composition distribution can be observed.

The energy information of the signal electrons is extracted by performing the pulse height discrimination using the present detector having the plurality of detection elements capable of individually detecting the signals described above, and an effect of improving the visibility at the time of observing the structure in the depth direction or the composition distribution of the sample 7 is obtained. For example, in a case where a measurement device such as an SEM includes a plurality of detection elements that each include at least a light emitting element and a light receiving element and can individually detect signals, an image is created based on information related to the energy or the number of signal electrons, and thus a user can visually recognize a structure or the like in the depth direction in the image more satisfactorily.

In Embodiments 1 to 8, the incident surface 10i of the light emitting element is a spherical surface or the like, the incident angle θi is small, and the energy of the signal electrons is sufficiently absorbed, and these configurations are suitable for energy discrimination. This is because, in the energy discrimination, the energy of the signal electrons is absorbed as much as possible, and the energy is measured based on a light emitting amount generated by the energy, but when the light emitting amount changes depending on the incident angle, it is unclear which of the energy and the angle is to be discriminated. Therefore, in the case of discriminating the energy, the incident angle θi is required to be small, and it is particularly preferable to set the incident angle θi to be smaller than 30 degrees.

FIG. 16C shows an example of a graphical user interface 16 (GUI) when the visibility is improved by the energy discrimination (pulse height discrimination). This GUI is a GUI when energy discrimination is performed using the detector described in Embodiment 7. The azimuth angle direction is divided into 12 directions, and the polar angle direction is divided into three directions. At the top of the GUI, a filtering image 16a created by energy discrimination and an image 16b using all signals are displayed. Based on these images, the visibility of the filtering image can be improved as described below.

This example is a display example when the sample 7 is irradiated with the electron beam 101 of 50 keV, and the maximum energy of the signal electrons 102 is 50 keV, which is the same as the energy of the electron beam 101.

Three graphs in the middle of the GUI show energy spectra of detection elements, and respectively indicate a spectrum 16c, a spectrum 16d, and a spectrum 16e. In this example, the spectrum 16c is a spectrum obtained by averaging spectra detected by detection elements on a radially outer side in 12 azimuth angle directions. Similarly, the spectra 16d and 16e are spectra corresponding to the signal electrons detected by a detection element at a radially intermediate position and a detection element on a radially outer side. That is, the spectrum 16c is a spectrum corresponding to the signal electrons 102 detected when the signal electrons 102 fly in a direction with a small polar angle, and the spectra 16d and 16e are spectra corresponding to the signal electrons detected when the signal electrons fly in a direction with an intermediate polar angle and a direction with a large polar angle, respectively. By displaying a spectrum for each polar angle, the energy discrimination and the polar angle discrimination are easily performed at the same time. The middle graph may be generated for each light receiving element. Further, a numerical value may be output to a file or the like as spectrum data.

In the three graphs displayed in the middle of the GUI, a horizontal axis represents energy, and a vertical axis represents a frequency of detection of signal electrons corresponding to each energy. The horizontal axis represents an amount related to energy such as a pulse height value. A solid line and a broken line in each graph are energy spectra at positions indicated by a circle and a triangle in the filtering image. In the present example, a material of the sample is different between the positions indicated by the circle and the triangle.

An energy band to be used for creating the filtering image is selected using the energy spectra. The energy band used for creating an image is positioned between a dotted line 16j and a one-dot chain line 16k. In the present example, in the spectra 16c and 16d, since a frequency of the circle (a solid line) is higher than a frequency of the triangle (a broken line) in all the energy bands, signals in all the energy bands are acquired to increase the contrast. In the spectrum 16e, the dotted line 16j representing a lower limit is set to energy larger than an intersection point between the frequency of the circle and the frequency of the triangle so that the frequency of the circle is a larger than the frequency of the triangle only in a region. The one-dot chain line 16k representing an upper limit is set to a value slightly smaller than a maximum value of the energy in order to exclude a region having a small frequency difference.

It is needless to say that a method for selecting an energy band used for creating an image is not limited thereto, and there are various algorithms. These algorithms may be implemented as programs and mounted in the charged particle beam apparatus 1, or programs (including a script, a macro, and the like) describing these algorithms may be read and executed later. The charged particle beam apparatus 1 may include a processor, and the processor may execute a program to cause the charged particle beam apparatus 1 to implement the function of each embodiment.

Data to be displayed in the filtering image 16a is selected according to check boxes 16f. “S”, “M”, and “H” that label the check boxes 16f indicate data sets corresponding to the spectra 16c, 16d, and 16e, respectively. When “H” is checked, the filtering image 16a is created using electrical signals of the signal electrons 102 belonging to an energy band sandwiched between the dotted line 16j and the one-dot chain line 16k in the spectrum 16e. When all the check boxes 16f are checked, the image 16a is created using electrical signals of the signal electrons 102 belonging to an energy band sandwiched between the dotted line 16j and the one-dot chain line 16k in all the spectra 16c, 16d, and 16e.

In pull-down menus 16g, data processing in the azimuth angle direction is selected for creation of the spectra 16c, 16d, and 16e. In FIG. 16C, “average” for averaging spectra in 12 azimuth angle directions is selected. Alternatively, it is also possible to average only spectra of a part of detection elements (for example, detection elements belonging to the detection element group 5g6 to 5g8 in FIG. 11B), or designate only spectra of detection elements belonging to the detection element group 5g1. In this manner, various kinds of processing can be executed by the pull-down menus 16g, and setting for improving visibility of an image can be appropriately performed. Contents of the pull-down menus 16g can be appropriately set by those skilled in the art.

Text boxes 16h and text boxes 16i respectively indicate a minimum value and a maximum value of an energy band when the filtering image 16a is created, that is, values of the dotted line 16j and the one-dot chain line 16k in the spectra 16c, 16d, and 16e. When numerical values are input to these text boxes, the charged particle beam apparatus 1 may set and indicate the input values as a minimum value and a maximum value of an energy band. Alternatively, when a user moves the dotted line 16j and the one-dot chain line 16k on the GUI, the charged particle beam apparatus 1 may set values after the movement as the minimum value and the maximum value of an energy band and display the values in the text boxes.

It is convenient to create the filtering image 16a with good visibility using such a GUI, and since the visibility is good, it is easy to construct an image with good visibility. In the present example, a difference in signal amount (frequency difference) between the positions indicated by the circle and the triangle, that is, an increase in contrast is used as an index of good visibility. However, the invention is not limited thereto, and the good visibility may be appropriately set based on a signal-to-noise ratio (SNR), a contrast-to-noise ratio (CNR), or the like.

In addition, the GUI is often manually performed. Alternatively, the GUI can be appropriately automated, and various optimization methods such as Bayesian optimization, Artificial Intelligence (AI), and the like can be used at the time of automation.

As in Embodiments 6 to 8, in the measurement device having a detector capable of individually detecting pulses, by using the GUI that displays an energy spectrum, an amount related to energy such as a pulse height, or an item related to control of the amount, and displays an amount related to an azimuth or a position of the detector or an item related to control of the amount, it is possible to easily improve visibility by energy (pulse height) discrimination and angle discrimination such as a polar angle, and thus it is possible to construct an optimum image.

It is needless to say that when an algorithm is created in advance, there may be a GUI that omits display of a control GUI (a check box, a text box, a pull-down menu, and the like) and creates a filtering image in a fully automated manner. However, at the time of creating an algorithm or at the time of fine adjusting visibility, it is convenient to have a function of outputting spectrum data or a function of reading a program for such a control GUI or for each polar angle.

The GUI described in the present embodiment is an example, and various other forms can be adopted. For example, the GUI may be a GUI specialized for polar angle discrimination or a GUI specialized for energy discrimination.

Although an electron microscope using an electron beam, in particular, a scanning electron microscope has been described as an example of a charged particle beam apparatus in the embodiments of the present specification, the invention is not limited thereto as described at the beginning of Embodiment 1.

A quantum beam with which a sample is irradiated is not limited to the electron beam, and may be a particle beam such as ions or a beam such as X-rays or gamma rays.

In addition, the detector exhibits a better effect when the detector is a compact detector placed near the observation point, but the invention is not limited thereto.

The observation point is not limited to a beam irradiation position of the sample, and may be a collision point of two beams. In addition, the present technique is also effective for a detector placed at a position far from the observation point, a detector installed in a narrow portion, a detector in which a shape of an emission surface of a light emitting element and a shape of a light receiving surface of a light receiving element are different, and the like, and various applications are conceivable.

The invention is not limited to the embodiments described above, and includes various modifications. For example, the embodiments described above have been described in detail to facilitate understanding of the invention, and the invention is not necessarily limited to those including all configurations described above. A part of a configuration of a certain embodiment can be replaced with a configuration of another embodiment, and a part of a configuration of another embodiment can be added to a configuration of a certain embodiment. It is possible to add, delete, or replace a part of configurations of each embodiment with other configurations.

### REFERENCE SIGNS LIST

1 charged particle beam apparatus (measurement device)
2 electron source
3 scanning deflector
4 objective lens
5 detector
6 sample conveyance stage
7 sample
8 system control unit
9 monitor
10 light emitting element
11 light guide
12 light receiving element
13 mounting substrate
14 opening
15 detection circuit
16 graphical user interface
101 electron beam
102 signal electron
C central axis
φ azimuth angle
θo polar angle
CP vertex
D1 arrow (first direction)
D2 arrow (second direction)
EP light emitting point
MP observation point

1. A detector comprising:
a light emitting element configured to emit light due to collision of a quantum emitted from a sample by irradiating the sample with a beam; and
a plurality of light receiving elements each configured to receive light generated by the light emitting element on a light receiving surface, wherein
the light receiving surface is disposed at a position farther from the beam than the light emitting element in a first direction intersecting an irradiation direction of the beam,
the light receiving surface is disposed in a direction intersecting the irradiation direction of the beam, and
the detector forms
a first optical path that guides light in the first direction and
a second optical path that guides light arriving via the first optical path toward the light receiving surface.

2. The detector according to claim 1, wherein
the detector includes a light guide, and
the light guide forms at least a part of the second optical path.

3. The detector according to claim 1, wherein
the detector includes a surface that reflects light, which arrives in a direction orthogonal to the irradiation direction of the beam, in a direction having a component in a direction opposite to the irradiation direction of the beam.

4. The detector according to claim 1, wherein
a plurality of the light receiving surfaces are arranged along the first direction.

5. The detector according to claim 1, wherein
a plurality of the light emitting elements are arranged in the irradiation direction of the beam.

6. The detector according to claim 2, wherein
a plurality of the light emitting elements are arranged in the irradiation direction of the beam, and
a plurality of light guides connected to a plurality of light emitting elements have portions overlapping one another in the irradiation direction of the beam.

7. The detector according to claim 2, wherein
the light emitting element, the light guide, and the light receiving element are positioned on a same straight line in the first direction.

8. The detector according to claim 2, wherein
a width of the light guide is 1.5 times or less a width of the light receiving surface.

9. The detector according to claim 1, wherein
a plurality of the light emitting elements are arranged in a circumferential direction of the beam.

10. The detector according to claim 2, wherein
the light receiving surface of the light receiving element and the light guide are bonded to each other.

11. The detector according to claim 1, wherein
the light receiving element is a silicon photomultiplier.

12. The detector according to claim 1, wherein
the light emitting element is disposed such that an incident angle of the quantum on the light emitting element is 30 degrees or less.

13. The detector according to claim 1, wherein
at least one of an incident surface of the light emitting element on which the quantum is incident and a surface of the light emitting element opposite to the incident surface in the irradiation direction of the beam is inclined relative to the first direction.

14. The detector according to claim 2, wherein
a surface of the light guide opposite to an incident surface of the light emitting element in the irradiation direction of the beam is inclined relative to the first direction.

15. The detector according to claim 11, wherein
the detector includes a plurality of the silicon photomultipliers, and
operating voltages applied to the plurality of silicon photomultipliers are the same.

16. The detector according to claim 2, wherein
the light guide forms the first optical path and the second optical path.

17. The detector according to claim 1, wherein
the first optical path is formed to include at least one of
a surface that reflects light, which has a component in the first direction and a component in a direction opposite to the irradiation direction of the beam, in a direction having a component in the first direction and a component in the irradiation direction of the beam and
a surface that reflects light, which has a component in the first direction and a component in the irradiation direction of the beam, in a direction having a component in the first direction and a component in a direction opposite to the irradiation direction of the beam.

18. A detector comprising:
a light emitting element configured to emit light due to collision of a quantum emitted from a sample by irradiating the sample with a beam; and
a plurality of light receiving elements each configured to receive light generated by the light emitting element on a light receiving surface, wherein
the light receiving surface is disposed at a position farther from the beam than the light emitting element in a first direction intersecting an irradiation direction of the beam,
the detector has a transparent region for propagating light from a surface of the light emitting element where the quantum is incident to the light receiving surface, and
a normal line of the light receiving surface forms an angle of 45 degrees or less with the first direction.

19. A measurement device comprising:
the detector according to claim 1.

20. The measurement device according to claim 19, further comprising:
a plurality of detection elements each including at least the light emitting element and the light receiving element and configured to individually detect a signal, wherein
the measurement device creates an image based on information related to energy or the number of the quanta.

21. A charged particle beam apparatus comprising:
the detector according to claim 1.
